(19) United States
(12) Patent Application Publication
(10) Pub. No.: US 2017/0162516 A1
(43) Pub. Date: Jun. 8, 2017

(54) SEMICONDUCTOR PACKAGES INCLUDING SIDE SHIELDING PARTS

(71) Applicant: SK hynix Inc., Icheon-si Gyeonggi-do (KR)

(72) Inventor: Cheol Ho JOH, Icheon-si Gyeonggi-do (KR)

(21) Appl. No.: 15/159,987

(22) Filed: May 20, 2016

(30) Foreign Application Priority Data
Dec. 8, 2015 (KR) 10-2015-0174365

(51) Int. Cl. H01L 23/552; H01L 25/065; H01L 21/56; H01L 23/00; H01L 21/78; H01L 23/498; H01L 23/31

(52) U.S. Cl. CPC H01L 23/552; H01L 23/49838; H01L 25/0655; H01L 23/3128; H01L 24/49; H01L 24/32; H01L 24/73; H01L 23/49827; H01L 21/78; H01L 24/97; H01L 21/565; H01L 2224/32225; H01L 2224/48091; H01L 2224/48106; H01L 2224/48228; H01L 2224/73265; H01L 2924/3025; H01L 2924/15311; H01L 2924/1431; H01L 2924/1433; H01L 2924/1436; H01L 2924/1437; H01L 2924/1443; H01L 2924/1438; H01L 2924/01047

(57) ABSTRACT

A method of fabricating a semiconductor package is provided. The method includes providing a package substrate strip including chip mounting regions, bridge regions connecting the chip mounting regions to each other, and through slits disposed between the chip mounting regions. A side shielding part including a lower portion filling the through slits and an upper portion upwardly extending from the lower side shielding part to protrude from the package substrate strip is formed. Semiconductor chips are mounted on the chip mounting regions. Mold patterns are formed on the package substrate strip to cover the semiconductor chips and to expose a top surface of the side shielding part. A top shielding part is formed on the mold patterns to contact the side shielding part.

### CROSS-REFERENCE TO RELATED APPLICATION

The present application claims priority under 35 U.S.C 119(a) to Korean Patent Application No. 10-2015-0174365, filed on Dec. 8, 2015, which is incorporated herein by references in its entirety.

### BACKGROUND

1. Technical Field

Embodiments of the present disclosure relate to semiconductor packages and, more particularly, to semiconductor packages including side shielding parts and methods of fabricating the same.

2. Related Art

Semiconductor chips (also, referred as ‘semiconductor dies’) including integrated circuits have to be protected from electromagnetic waves that can affect operations of the integrated circuits. In addition, while the semiconductor chips operate, the integrated circuits may generate electromagnetic waves. The electromagnetic waves may also affect human bodies. That is, the electromagnetic waves generated from integrated circuits of semiconductor chips may affect other semiconductor chips, other electronic systems, or human bodies to cause malfunction of the other semiconductor chips or the other electronic systems or cause human diseases. Thus, it may be necessary to shield semiconductor chips (or the electronic systems) such that electromagnetic waves or high frequency noises generated from the semiconductor chips (or the electronic systems) are not propagated from the semiconductor chips.

Recently, wearable electronic devices and mobile devices are increasingly in demand with the development of lighter, smaller, faster, multi-functional, and higher performance electronic systems. Thus, it becomes more and more important to shield electronic products such as semiconductor packages from electromagnetic interference (hereinafter, referred to as ‘EMI’).

### SUMMARY

According to an embodiment, there is provided a method of fabricating a semiconductor package. The method includes providing a package substrate strip including a plurality of chip mounting regions, bridge regions connecting the plurality of chip mounting regions to each other, and a plurality of through slits disposed between the plurality of chip mounting regions. The through slits are filled with a conductive material to form a first side shielding part. A second side shielding part is formed to be vertically aligned with the first side shielding part. The second side shielding part is formed to upwardly protrude from the package substrate strip. A plurality of semiconductor chips are mounted on the plurality of chip mounting regions. Mold patterns are formed on the package substrate strip to cover the plurality of semiconductor chips and to expose a top surface of the second side shielding part. A top shielding part is formed on the mold patterns to be connected to the second side shielding part. The package substrate strip including the top shielding part are cut along a central region of the first and second side shielding parts to provide a plurality of unit semiconductor packages separated from each other.

According to another embodiment, there is provided a method of fabricating a semiconductor package. The method includes providing a package substrate strip including a plurality of chip mounting regions, bridge regions connecting the plurality of chip mounting regions to each other, and a plurality of through slits disposed between the plurality of chip mounting regions. A side shielding part including a lower side shielding part and an upper side shielding part is formed. The lower side shielding part is formed to fill the through slits, and the upper side shielding part is formed to upwardly extending from the lower side shielding part and to protrude from the package substrate strip. A plurality of semiconductor chips are mounted on the plurality of chip mounting regions. Mold patterns are formed on the package substrate strip to cover the plurality of semiconductor chips and to expose a top surface of the side shielding part. A top shielding part is formed on the mold patterns to be connected to the side shielding part. The package substrate strip including the top shielding part is cut along a central region of the side shielding part to provide a plurality of unit semiconductor packages separated from each other.

According to another embodiment, a semiconductor package includes a package substrate strip. The package substrate strip includes a plurality of chip mounting regions, bridge regions connecting the plurality of chip mounting regions to each other, and a plurality of through slits disposed between the plurality of chip mounting regions. A first side shielding part including a conductive material is disposed to fill the through slits. A second side shielding part is disposed to vertically overlap with the first side shielding part and to upwardly protrude from the package substrate strip. A plurality of semiconductor chips are mounted on the plurality of chip mounting regions. Mold patterns are disposed on the package substrate strip to cover the plurality of semiconductor chips and to expose a top surface of the second side shielding part. A top shielding part is disposed to cover the mold patterns and to contact the top surface of the second side shielding part.

According to another embodiment, a semiconductor package includes a package substrate including a chip mounting region, through slits defining the chip mounting region, and bridge regions disposed between the through slits along a periphery of the chip mounting region. A first side shielding part comprised of a conductive material fills the through slits to horizontally shield the chip mounting region. A second side shielding part vertically overlaps with the first side shielding part to upwardly protrude from the package substrate. A semiconductor chip is mounted on the chip mounting region. A mold pattern is disposed on the package substrate to cover the semiconductor chip and to expose a top surface of the second side shielding part. A top shielding part covers the mold pattern and contacts the top surface of the second side shielding part.

According to another embodiment, a semiconductor package includes a package substrate strip including a plurality of chip mounting regions, bridge regions connecting the plurality of chip mounting regions to each other, and a plurality of through slits disposed between the plurality of chip mounting regions. A side shielding part including a lower side shielding part and an upper side shielding part. The lower side shielding part fills the through slits, and the upper side shielding part upwardly extends from the lower side shielding part to protrude from the package substrate strip. A plurality of semiconductor chips are mounted on the plurality of chip mounting regions. Mold patterns are disposed on the package substrate strip to cover the plurality of semiconductor chips and to expose a top surface of the side shielding part. A top shielding part is disposed on the mold patterns to contact the top surface of the side shielding part.

According to another embodiment, a semiconductor package includes a package substrate including a chip mounting region, through slits defining the chip mounting region, bridge regions disposed between the through slits, and edge shielding pillars penetrating each of the bridge regions. A side shielding part including a lower side shielding part and an upper side shielding part is provided. The lower side shielding part fills the through slits, and the upper side shielding part upwardly extends from the lower side shielding part to protrude from the package substrate. A semiconductor chip is mounted on the chip mounting region. A mold pattern is disposed on the package substrate to cover the semiconductor chip and to expose a top surface of the side shielding part. A top shielding part is disposed on the mold pattern to contact the top surface of the side shielding part.

According to another embodiment, a memory card includes a semiconductor package. The semiconductor package includes a package substrate strip. The package substrate strip includes a plurality of chip mounting regions, bridge regions connecting the plurality of chip mounting regions to each other, and a plurality of through slits disposed between the plurality of chip mounting regions. A first side shielding part comprised of a conductive material is disposed to fill the through slits. A second side shielding part is disposed to vertically overlap with the first side shielding part and to upwardly protrude from the package substrate strip. A plurality of semiconductor chips are mounted on the plurality of chip mounting regions. Mold patterns are disposed on the package substrate strip to cover the plurality of semiconductor chips and to expose a top surface of the second side shielding part. A top shielding part is disposed to cover the mold patterns and to contact the top surface of the second side shielding part.

According to another embodiment, a memory card includes a semiconductor package. The semiconductor package includes a package substrate including a chip mounting region, through slits defining the chip mounting region, and bridge regions disposed between the through slits along a periphery of the chip mounting region. A first side shielding part comprised of a conductive material fills the through slits to horizontally shield the chip mounting region. A second side shielding part vertically overlaps with the first side shielding part to upwardly protrude from the package substrate. A semiconductor chip is mounted on the chip mounting region. A mold pattern is disposed on the package substrate to cover the semiconductor chip and to expose a top surface of the second side shielding part. A top shielding part covers the mold pattern and contacts the top surface of the second side shielding part.

According to another embodiment, a memory card includes a semiconductor package. The semiconductor package includes a package substrate strip including a plurality of chip mounting regions, bridge regions connecting the plurality of chip mounting regions to each other, and a plurality of through slits disposed between the plurality of chip mounting regions. A side shielding part including a lower side shielding part and an upper side shielding part is disposed. The lower side shielding part fills the through slits, and the upper side shielding part upwardly extends from the lower side shielding part to protrude from the package substrate strip. A plurality of semiconductor chips are mounted on the plurality of chip mounting regions. Mold patterns are disposed on the package substrate strip to cover the plurality of semiconductor chips and to expose a top surface of the side shielding part. A top shielding part is disposed on the mold patterns to contact the top surface of the side shielding part.

According to another embodiment, a memory card includes a semiconductor package. The semiconductor package includes a package substrate including a chip mounting region, through slits defining the chip mounting region, bridge regions disposed between the through slits, and edge shielding pillars penetrating each of the bridge regions. A side shielding part including a lower side shielding part and an upper side shielding part is provided. The lower side shielding part fills the through slits, and the upper side shielding part upwardly extends from the lower side shielding part to protrude from the package substrate. A semiconductor chip is mounted on the chip mounting region. A mold pattern is disposed on the package substrate to cover the semiconductor chip and to expose a top surface of the side shielding part. A top shielding part is disposed on the mold pattern to contact the top surface of the side shielding part.

According to another embodiment, an electronic system includes a semiconductor package. The semiconductor package includes a package substrate strip. The package substrate strip includes a plurality of chip mounting regions, bridge regions connecting the plurality of chip mounting regions to each other, and a plurality of through slits disposed between the plurality of chip mounting regions. A first side shielding part is disposed to fill the through slits. A second side shielding part is disposed to vertically overlap with the first side shielding part and to upwardly protrude from the package substrate strip. A plurality of semiconductor chips are mounted on the plurality of chip mounting regions. Mold patterns are disposed on the package substrate strip to cover the plurality of semiconductor chips and to expose a top surface of the second side shielding part. A top shielding part is disposed to cover the mold patterns and to contact the top surface of the second side shielding part.

According to another embodiment, an electronic system includes a semiconductor package. The semiconductor package includes a package substrate including a chip mounting region, through slits defining the chip mounting region, and bridge regions disposed between the through slits along a periphery of the chip mounting region. A first side shielding part comprised of a conductive material fills the through slits to horizontally shield the chip mounting region. A second side shielding part vertically overlaps with the first side shielding part to upwardly protrude from the package substrate. A semiconductor chip is mounted on the chip mounting region. A mold pattern is disposed on the package substrate to cover the semiconductor chip and to expose a top surface of the second side shielding part. A top shielding part covers the mold pattern and contacts the top surface of the second side shielding part.

According to another embodiment, an electronic system includes a semiconductor package. The semiconductor package includes a package substrate strip including a plurality of chip mounting regions, bridge regions connecting the plurality of chip mounting regions to each other, and a plurality of through slits disposed between the plurality of chip mounting regions. A side shielding part including a lower side shielding part and an upper side shielding part. The lower side shielding part fills the through slits, and the upper side shielding part upwardly extends from the lower side shielding part to protrude from the package substrate strip. A plurality of semiconductor chips are mounted on the plurality of chip mounting regions. Mold patterns are disposed on the package substrate strip to cover the plurality of semiconductor chips and to expose a top surface of the side shielding part. A top shielding part is disposed on the mold patterns to contact the top surface of the side shielding part.

According to another embodiment, an electronic system includes a semiconductor package. The semiconductor package includes a package substrate including a chip mounting region, through slits defining the chip mounting region, bridge regions disposed between the through slits, and edge shielding pillars penetrating each of the bridge regions. A side shielding part including a lower side shielding part and an upper side shielding part is provided. The lower side shielding part fills the through slits, and the upper side shielding part upwardly extends from the lower side shielding part to protrude from the package substrate. A semiconductor chip is mounted on the chip mounting region. A mold pattern is disposed on the package substrate to cover the semiconductor chip and to expose a top surface of the side shielding part. A top shielding part is disposed on the mold pattern to contact the top surface of the side shielding part.

### BRIEF DESCRIPTION OF THE DRAWINGS

FIGS. 1 to 7 illustrate a package substrate strip of a semiconductor package according to an embodiment.

FIGS. 8 to 31D illustrate a method of fabricating semiconductor packages and semiconductor packages fabricated thereby according to an embodiment.

FIG. 32 is a cross-sectional view illustrating a semiconductor package according to an embodiment.

FIGS. 33 to 48 are cross-sectional views illustrating a method of fabricating semiconductor packages and semiconductor packages fabricated thereby according to another embodiment.

FIG. 49 is a cross-sectional view illustrating a semiconductor package according to another embodiment.

FIG. 50 is a block diagram illustrating an electronic system employing a memory card including a package according to an embodiment.

FIG. 51 is a block diagram illustrating an electronic system including a package according to an embodiment.

### DESCRIPTION OF SPECIFIC EMBODIMENTS

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the inventive concept.

Spatially relative terms, such as “beneath,” “below,” “lower,” “above,” “upper,” “top,” “bottom” and the like, may be used to describe an element and/or features relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

A semiconductor package may include electronic devices such as semiconductor chips or semiconductor dies. The semiconductor chips or the semiconductor dies may be obtained by separating a semiconductor substrate such as a wafer into a plurality of pieces using a die sawing process. The semiconductor chips or the semiconductor dies may correspond to memory chips or logic chips (including application specific integrated circuits (ASIC) chips). The memory chips may include dynamic random access memory (DRAM) circuits, static random access memory (SRAM) circuits, flash circuits, magnetic random access memory (MRAM) circuits, resistive random access memory (ReRAM) circuits, ferroelectric random access memory (FeRAM) circuits, or phase change random access memory (PcRAM) circuits which are integrated on the semiconductor substrate. The logic chips may include logic circuits which are integrated on the semiconductor substrate. A package substrate may be a substrate for electrically connecting a semiconductor chip to an external device. Accordingly, the package substrate may include a plurality of circuit traces disposed on and/or in a substrate body comprised of a dielectric material. The semiconductor package may be employed in communication systems such as mobile phones, electronic systems associated with biotechnology or health care, or wearable electronic systems.

Same reference numerals refer to same elements throughout the specification. Thus, even though a reference numeral is not mentioned or described with reference to a drawing, the reference numeral may be mentioned or described with reference to another drawing. In addition, even though a reference numeral is not shown in a drawing, it may be mentioned or described with reference to another drawing.

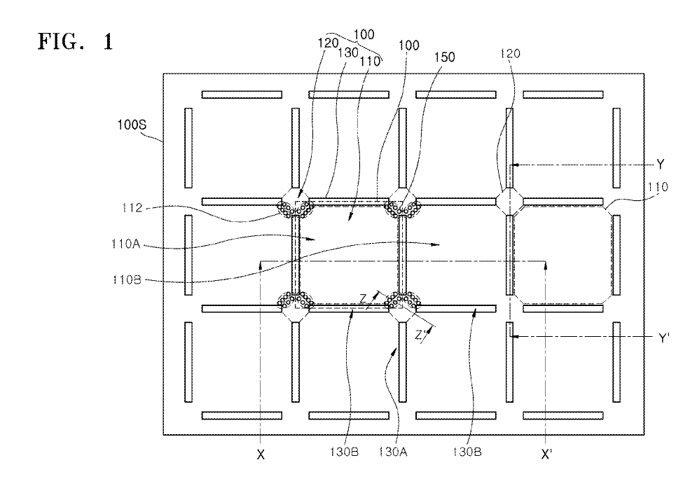

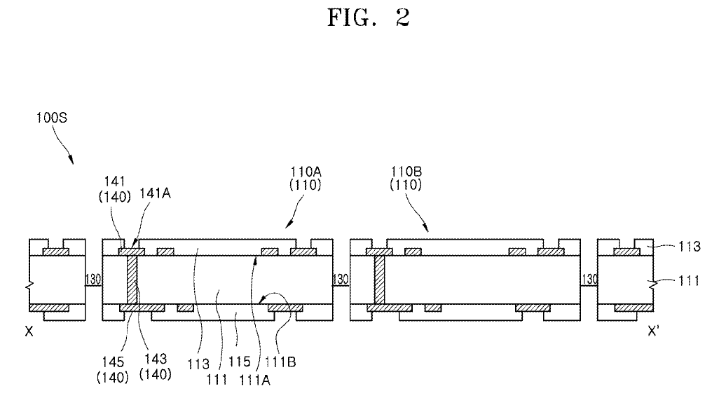

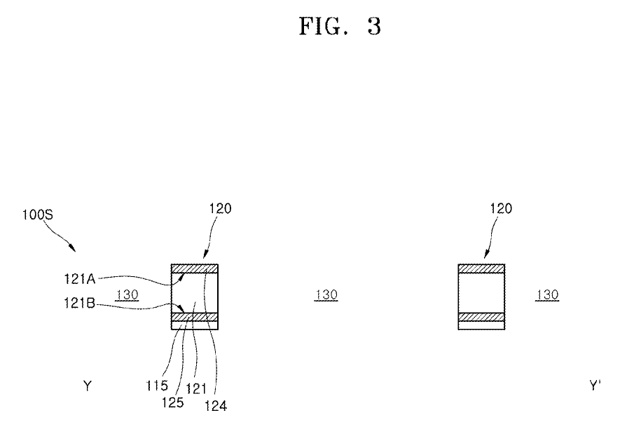

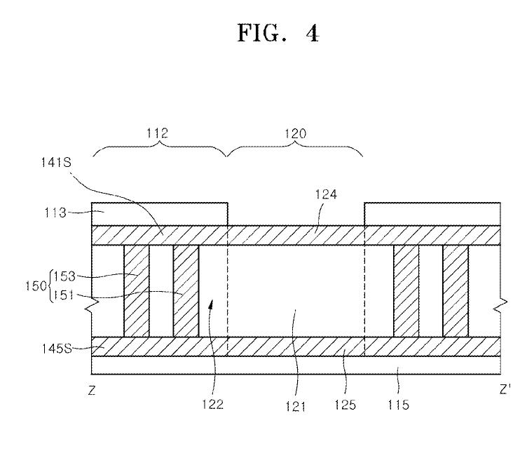

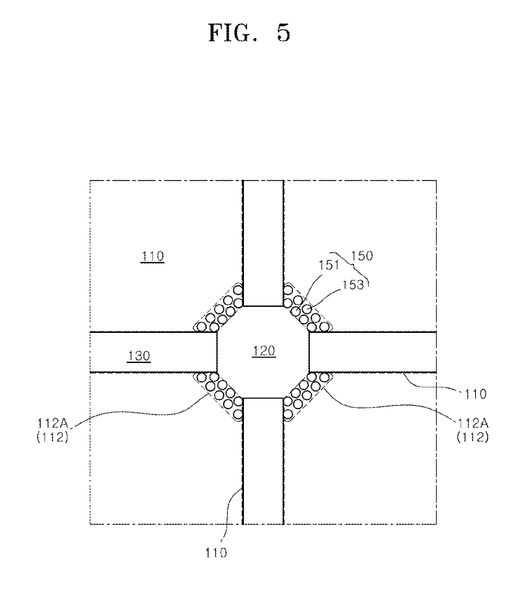

FIG. 1 is a plan view illustrating a package substrate strip 100S for realizing a semiconductor package according to an embodiment. FIG. 2 is a cross-sectional view taken along a line X-X′ of FIG. 1, FIG. 3 is a cross-sectional view taken along a line Y-Y′ of FIG. 1, and FIG. 4 is a cross-sectional view taken along a line Z-Z′ of FIG. 1. The line X-X′ of FIG. 1 intersects the line Y-Y′ of FIG. 1 at a right angle, and the line Z-Z′ of FIG. 1 is a line extending in a diagonal direction between the line X-X′ and the line Y-Y′ of FIG. 1. FIGS. 5 to 7 are plan views illustrating edge shielding pillars 150, which may be conductive, included in the package substrate strip 100S of FIG. 1.

Referring to FIG. 1, the package substrate strip 100S may be prepared to provide a plurality of unit package substrates 100, each of which is employed in a semiconductor package. The unit package substrates 100 may be separated from each other and may be used as package substrates of semiconductor packages. That is, semiconductor chips may be mounted on the unit package substrates 100 to constitute the semiconductor packages. A plurality of unit package substrates 100 may be connected to each other to constitute the package substrate strip 100S.

The package substrate strip 100S may include a plurality of chip mounting regions 110. The chip mounting regions 110 may be arrayed in rows and columns on the package substrate strip 100S to have a matrix form. That is, the chip mounting regions 110 may be disposed to have a mosaic array. Each of the plurality of chip mounting regions 110 may have a rectangular shape in a plan view. Through slits 130 may be disposed between the chip mounting regions 110 to define the chip mounting regions 110. Each of the through slits 130 may vertically penetrate the package substrate strip 100S between two adjacent chip mounting regions 110A and 1108 of the chip mounting regions 110, as illustrated in FIG. 2. Each (e.g., the chip mounting region 110A) of the chip mounting regions 110 may be surrounded by some of the through slits 130. The through slits 130 may be disposed in boundary regions between the chip mounting regions 110. Thus, the chip mounting regions 110 may be defined by the through slits 130. Accordingly, each of the chip mounting regions 110 may be set to be surrounded by some of the through slits 130.

If the through slits 130 are formed to fully surround the chip mounting regions 110, the chip mounting regions 110 may be separated and removed from the package substrate strip 100S. However, the package substrate strip 100S may be used as a tool for carrying and fixing the chip mounting regions 110 to simultaneously mount semiconductor chips on the chip mounting regions 110 during a packaging process. Thus, the chip mounting regions 110 may be connected to each other by the package substrate strip 100S during the packaging process. Accordingly, the package substrate strip 100S may be designed so that each of the chip mounting regions 110 is surrounded by some separate through slits 130 and bridge regions 120 that are disposed between the separate through slits 130 to physically connect each chip mounting region 110 to the package substrate strip 100S.

The bridge regions 120 may constitute a net that connects the chip mounting regions 110 to each other. As illustrated in FIG. 3, the bridge regions 120 may correspond to portions of the unit package substrates 100, which are located between the through slits 130 that are adjacent to each other. As illustrated in FIG. 1, the bridge regions 120 may correspond to portions of the unit package substrate 100, which are located at four corner edges of each of the chip mounting regions 110. Since the bridge regions 120 are located at four corner edges of each of the chip mounting regions 110, the bridge regions 120 may be disposed to be point symmetric with respect to a central point of each chip mounting region 110. Thus, the bridge regions 120 may prevent the chip mounting regions 110 from being twisted or distorted. That is, the bridge regions 120 act as a frame that fixes positions of the chip mounting regions 110. Alternatively, the bridge regions 120 may be disposed to be located at side edges of the chip mounting regions 110. Since two adjacent chip mounting regions 110 (e.g., the chip mounting regions 110A and 110B) are connected to each other by the bridge regions 120, any one of the two adjacent chip mounting regions 110 may be located at a specific position of the package substrate strip 100S.

Each of the unit package substrates 100 constituting the package substrate strip 100S may be set to include one of the chip mounting regions 110, portions of the through slits 130 surrounding the chip mounting regions 110, and portions of the bridge regions 120 connected to at least one of the chip mounting regions 110. In some embodiments, each of the unit package substrates 100 may be set to include two adjacent ones (e.g., the chip mounting regions 110A and 110B) of the chip mounting regions 110, a through slit 130A between the chip mounting regions 110A and 110B, through slits 130B surrounding a periphery of the chip mounting regions 110A and 110B, and portions of the bridge regions 120 between the through slits 130B. In such a case, the through slit 130A may be located at an inside region of the unit package substrate 100. The through slits 130 (including the through slits 130A and 130B) may be filled with a conductive material to provide side shielding parts that shield the chip mounting regions 110 from EMI.

Referring again to FIG. 1, an array of edge shielding pillars 150 may be disposed in a boundary portion 112 between the chip mounting region 110 and the bridge region 120 adjacent to the chip mounting region 110. The boundary portion 112 may include a portion the chip mounting region 110 which is adjacent to the bridge region 120. The boundary portion 112 may include a portion of the bridge region 120 which is adjacent to the chip mounting region 110. The boundary portion 112 may be an expanded portion including a portion of the chip mounting region 110 adjacent to the bridge region 120 and a portion of the bridge region 120 adjacent to the chip mounting region 110. Each of the edge shielding pillars 150 may have a shape of a through via that substantially penetrates the boundary portion 112 of the chip mounting region 110, as illustrated in FIG. 4. In some embodiments, the edge shielding pillars 150 in each boundary portion 112 may be arrayed in a line. Alternatively, the edge shielding pillars 150 in each boundary portion 112 may be arrayed in two or more lines to at least partially shield the chip mounting region 110 in at least a horizontal direction from EMI. The side shielding parts filling the through slits 130 and the edge shielding pillars 150 may shield the chip mounting regions 110 from EMI. Accordingly, each of the unit package substrates 100 constituting the package substrate strip 100S may include one of the chip mounting regions 110, portions of the through slits 130 surrounding one of the chip mounting regions 110, portions of the bridge regions 120 connected to one of the chip mounting regions 110, and the edge shielding pillars 150 penetrating corner edges of the one of the chip mounting regions 110.

Referring to FIGS. 1 and 2, each of the unit package substrates 100 constituting the package substrate strip 100S may include a circuit interconnection structure 140 which is electrically connected to an external device or a semiconductor chip to be mounted on the unit package substrate 100. Each of the chip mounting regions 110 may include a body layer 111 substantially acting as a package substrate. Circuit trace patterns 141, 143 and 145 constituting the circuit interconnection structure 140 may be disposed in and on the body layer 111. The body layer 111 may include a dielectric material. For example, the body layer 111 may include a core layer comprised of a resin material containing a fabric material.

The circuit interconnection structure 140 may include first trace patterns 141 which are electrically connected to a semiconductor chip to be mounted in the chip mounting region 110, second trace patterns 145 which are electrically connected to an external device, and internal trace patterns 143 disposed in the body layer 111. The internal trace patterns 143 may be disposed to penetrate the body layer 111. Some of the internal trace patterns 143 may have a shape of a via that electrically connects the first trace patterns 141 to the second trace patterns 145. Although FIG. 2 illustrates an example in which the first trace patterns 141 are disposed on one surface of the body layer 111 and the second trace patterns 145 are disposed on an other surface of the body layer 111 opposite to the first trace patterns 141, the present disclosure is not limited thereto. For example, in some embodiments, the body layer 111 may include a plurality of dielectric layers which are stacked, and the first and second trace patterns 141 and 145 may be additionally disposed between the plurality of dielectric layers constituting the body layer 111. The first and second trace patterns 141 and 145 may be routed to have various interconnection layouts.

The first trace patterns 141 may be disposed on a first surface 111A of the body layer 111, and a first dielectric layer 113 may be disposed on the first surface 111A of the body layer 111 to leave portions of the first trace patterns 141 exposed. The first dielectric layer 113 may include a solder resist material. The first dielectric layer 113 may have openings that leave portions 141A of the first trace patterns 141 exposed, where the exposed portions of the second trace patterns 145 may be used as bonding fingers or bonding pads that are connected to a semiconductor chip. The second trace patterns 145 may be disposed on a second surface 111B of the body layer 111 opposite to the first trace patterns 141, and a second dielectric layer 115 may be disposed on the second surface 111B of the body layer 111 to leave portions of the second trace patterns 145 exposed. The second dielectric layer 115 may include a solder resist material. The second dielectric layer 115 may have openings that leave portions of the second trace patterns 145 exposed, where the exposed portions of the second trace patterns 145 may be used as pads that are connected to external terminals such as solder balls. The through slits 130 may be provided to substantially penetrate the body layer 111 and the first and second dielectric layers 113 and 115.

Referring to FIGS. 1, 2 and 3, the bridge region 120 connecting two adjacent chip mounting regions 110 (e.g., the chip mounting regions 110A and 110B) to each other may be located between two adjacent through slits 130. A cross-section view of the bridge region 120 may be substantially the same as a cross-sectional view of the package substrate strip 100S. The bridge region 120 may correspond to a portion extending from the chip mounting regions 110. Thus, the bridge region 120 may also have a cross-sectional view which is fundamentally the same as a cross-sectional view of the chip mounting regions 110. For example, the body layer 111 may extend to provide a bridge body layer 121 constituting the bridge region 120, where the bridge body layer 121 may be comprised of a dielectric material. A first bridge trace pattern 124 may be formed on a first surface 121A of the bridge body layer 121, and a second bridge trace pattern 125 may be disposed on a second surface 121B of the bridge body layer 121.

The first bridge trace pattern 124 may correspond to an extension of one of the first trace patterns 141. The first trace patterns 141 may include signal lines for transmitting signals, a power line for supplying a power supply voltage, and a ground line for supplying a ground voltage. The first bridge trace pattern 124 may be connected to the ground line or may be a ground pattern extending from the ground line. The first bridge trace pattern 124 may include substantially the same metal material as the first trace patterns 141. For example, each of the first trace patterns 141 including the first bridge trace pattern 124 may include a copper material. The first dielectric layer 113 may have an opening that exposes the first bridge trace pattern 124 in the bridge region 120.

The second bridge trace pattern 125 may be connected to the ground line or may be a ground pattern extending from the ground line. The first and second bridge trace patterns 124 and 125 respectively disposed on the first and second surfaces 121A and 121B of the bridge body layer 121 may act as a reinforcing member that reinforces a strength of the bridge body layer 121. If a width of the bridge body layers 121 is reduced, a length of the through slits 130 may increase. In such a case, it may be less effective for the bridge body layers 121 to act as a frame for fixing and supporting the chip mounting regions 110 because a strength of the bridge body layers 121 is lowered. However, according to embodiments, the first and second bridge trace patterns 124 and 125 may be provided to reinforce a strength of the bridge body layers 121 so that the bridge body layers 121 more effectively act as a frame for fixing and supporting the chip mounting regions 110. The first and second bridge trace patterns 124 and 125 may be electrically connected to the side shielding parts filling the through slits 130. Thus, the first and second bridge trace patterns 124 and 125 may be used as ground paths for grounding an EMI shielding cage including the side shielding parts in the through slits 130.

Referring to FIGS. 1, 3 and 4, the bridge body layers 121 in the bridge regions 120 connecting the chip mounting regions 110 to each other are not comprised of a conductive material. Thus, electromagnetic waves or high frequency noises may propagate through the bridge regions 120. Accordingly, the array of the edge shielding pillars 150 that penetrate the bridge body layers 121 may be disposed in each boundary portion 112 between the chip mounting region 110 and the bridge region 120 adjacent to the chip mounting region 110 in order to at least partially shield the chip mounting region 110 in at least a horizontal direction from EMI. As illustrated in FIG. 4, each of the edge shielding pillars 150 may have a shape of a through via that substantially penetrates a package substrate body 122 located in the boundary portion 112.

Referring to FIGS. 1 and 4, the edge shielding pillars 150 may be arrayed in two lines, for example, in two columns. As illustrated in FIG. 5, the edge shielding pillars 150 arranged in two adjacent columns may also be arrayed in a zigzag fashion in a direction parallel with the two columns. FIG. 5 is an enlarged view illustrating the bridge region 120 of FIG. 1. Since the edge shielding pillars 150 are arrayed in a zigzag fashion in two columns, the chip mounting regions 110 may be effectively shielded from EMI by the edge shielding pillars 150. The edge shielding pillars 150 may include first edge shielding pillars 151 arrayed in a first column relatively closer to the bridge region 120 and second edge shielding pillars 153 arrayed in a second column relatively further from the bridge region 120 than the first edge shielding pillars 151. A distance between the first edge shielding pillars 151, a distance between the second edge shielding pillars 153, and a distance between the first edge shielding pillars 151 and the second edge shielding pillars 153 may be appropriately determined according to a wavelength of electromagnetic waves traveling toward the boundary portion 112. The edge shielding pillars 150 including the first edge shielding pillars 151 and the second edge shielding pillars 153 may be disposed in a boundary portion 112A located in an edge of the chip mounting region 110 adjacent to the bridge region 120. As illustrated in FIG. 4, the edge shielding pillars 150 may have a shape of vias that connect a first trace pattern 141S on a top surface of the package substrate body 122 to a second trace pattern 145S on a bottom surface of the package substrate body 122. The first trace pattern 141S may be a pattern extending from the first bridge trace pattern 124, and the second trace pattern 145S may be a pattern extending from the second bridge trace pattern 125. The second trace pattern 145S may be electrically connected to a ground terminal.

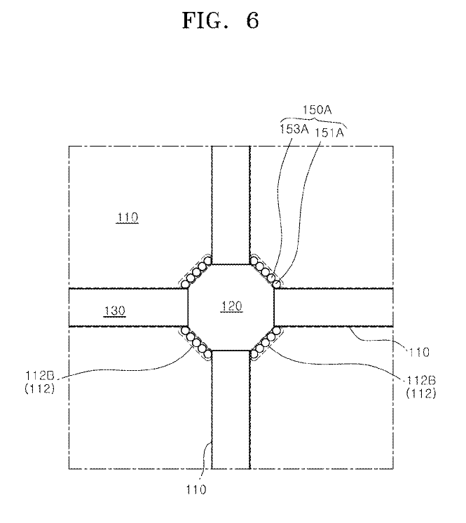

Referring to FIG. 6, an edge shielding wall 150A instead of the edge shielding pillars 150 shown in FIG. 5 may be disposed in the boundary portion 112. The edge shielding wall 150A may include first edge shielding pillars 151A and second edge shielding pillars 153A which are alternately arrayed in one column to be in contact with each other. While the edge shielding pillars 150 shown in FIG. 5 may be disposed to be spaced apart from each other by a certain distance, the first and second edge shielding pillars 151A and 153A constituting the edge shielding wall 150A may be in contact with each other in one column to provide a single wall. Thus, the edge shielding wall 150A may at least partially shield the chip mounting region 110 in at least a horizontal direction from EMI. The edge shielding wall 150A may be disposed in a boundary portion 112B located in an edge of the chip mounting region 110 adjacent to the bridge region 120.

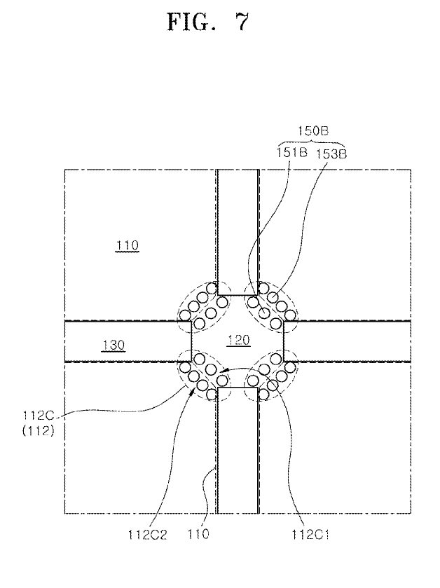

Referring to FIG. 7, which shows edge shielding pillars 150B disposed in a boundary portion 112C instead of the edge shielding pillars 150 shown in FIG. 5. First edge shielding pillars 151B among the edge shielding pillars 150B may be disposed in a first boundary portion 112C1 located in the bridge region 120, and second edge shielding pillars 153B among the edge shielding pillars 150B may be disposed in a second boundary portion 112C2 located in the chip mounting region 110 adjacent to the bridge region 120. Alternatively, all of the edge shielding pillars 150B may be disposed in the bridge region 120. The first boundary portion 112C1 and the second boundary portion 112C2 may constitute a boundary portion 112C.

A plurality of semiconductor packages may be simultaneously fabricated using the package substrate strip 100S that includes the through slits 130 disposed to surround the chip mounting regions 110.

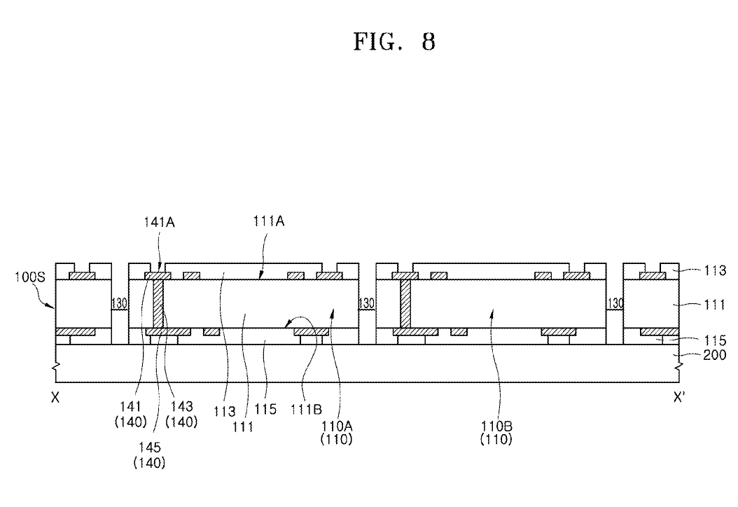

FIGS. 8 to 31 illustrate a method of fabricating semiconductor packages and semiconductor packages fabricated thereby.

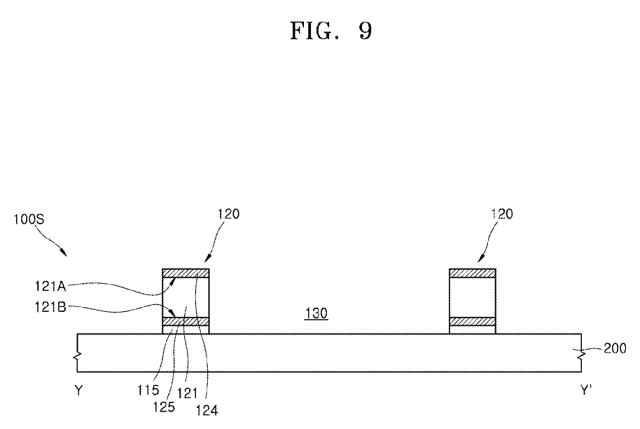

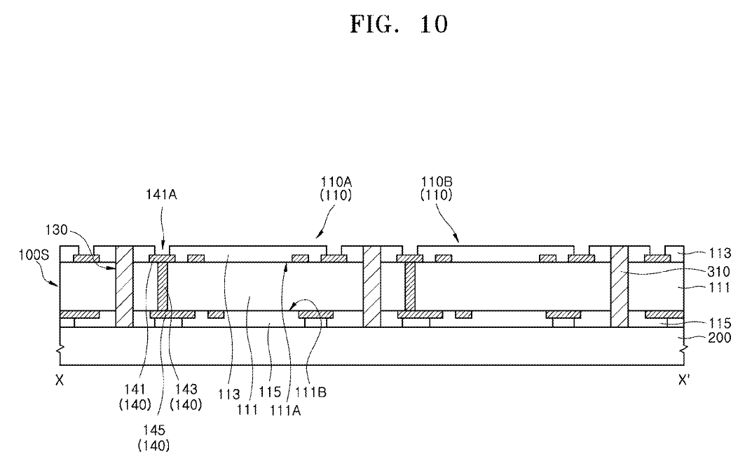

FIGS. 8 and 9 illustrate a step of attaching the package substrate strip 100S described with reference to FIGS. 1 to 7 to a carrier 200. FIG. 8 is a cross-sectional view taken along a line X-X′ of FIG. 1, and FIG. 9 is a cross-sectional view taken along a line Y-Y′ of FIG. 1.

Referring to FIGS. 8 and 9, the package substrate strip 100S may be located over the carrier 200 and may be attached to the carrier 200 using a lamination process. The package substrate strip 110s may be attached to the package to the carrier 200 before the through slits 130 are filled with the conductive material. The carrier 200 may have a shape of a tape. Although not shown in the drawings, an adhesive layer or a viscous layer may be provided between the package substrate strip 100S and the carrier 200 to fix the package substrate strip 100S to the carrier 200. Portions of the carrier 200 may be exposed by the through slits 130 of the package substrate strip 100S.

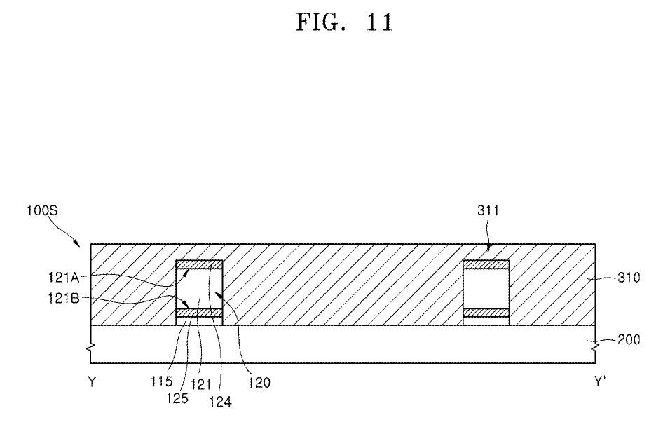

FIGS. 10 and 11 illustrate a step of forming a first or lower side shielding part 310 filling the through slits 130. FIG. 10 is a cross-sectional view taken along a line X-X′ of FIG. 1, and FIG. 11 is a cross-sectional view taken along a line Y-Y′ of FIG. 1.

Referring to FIGS. 10 and 11, the first side shielding part 310 filling the through slits 130 may be formed of a conductive material. Specifically, a first conductive adhesive may be coated on the package substrate strip 100S to form the first side shielding part 310 filling the through slits 130. The first conductive adhesive may be coated with a paste material having a relatively low viscosity. In such a case, the through slits 130 may be completely filled with the first conductive adhesive by a capillary phenomenon without any voids which is due to a shape of the through slits 130. The first conductive adhesive may be a paste material that is obtained by dispersing conductive particles such as solder particles in a resin material. Silver particles may be used as the conductive particles, and an epoxy resin material may be used as a matrix material of the resin material. The viscosity of the first conductive adhesive may be adjusted by controlling a composition ratio of the epoxy resin material as well as a size and a content of the conductive particles. The viscosity of the first conductive adhesive may be appropriately adjusted according to a size and an aspect ratio of the through slits 130. That is, the viscosity of the first conductive adhesive may be appropriately adjusted so that the through slits 130 are filled with the first conductive adhesive without any voids. After the first conductive adhesive is coated, the first conductive adhesive may be cured to form the first side shielding part 310 having a solid phase. The first side shielding part 310 may be formed to cover sidewalls of the chip mounting regions 110, which are exposed by the through slits 130.

Since the chip mounting regions 110 are connected and fixed to each other by the bridge regions 120, the bridge regions 120 may prevent the chip mounting regions 110 from being twisted or distorted. If at least one of the chip mounting regions 110 is twisted or distorted so that a position of the chip mounting region 110 changes, a width of the through slits 130 may change. In such a case, the first side shielding part 310 filling the through slits 130 may have a non-uniform width which may cause a process failure. However, according to the embodiments, the chip mounting regions 110 may be connected and fixed to each other by the bridge regions 120. Thus, no process failures may occur even after the first side shielding part 310 is formed.

As illustrated in FIG. 11, if top surfaces of the first bridge trace patterns 124 may possibly not be covered with the first dielectric layer (113 of FIG. 10), the top surfaces of the first bridge trace patterns 124 may be covered with extensions 311 of the first side shielding part 310. That is, the first side shielding part 310 may be formed so that a top surface of the first side shielding part 310 is located at a level which is higher than a level of the top surfaces of the first bridge trace patterns 124. The first side shielding part 310 may be formed so that the top surface of the first side shielding part 310 is located at a level which is coplanar with or higher than a level of a top surface of the first dielectric layer 113. Since the top surfaces of the first bridge trace patterns 124 overlap with the extensions 311 of the first side shielding part 310, a contact area between the first side shielding part 310 and the first bridge trace patterns 124 may increase. In such a case, the first side shielding part 310 may be more reliably grounded because the first bridge trace patterns 124 are used as ground paths.

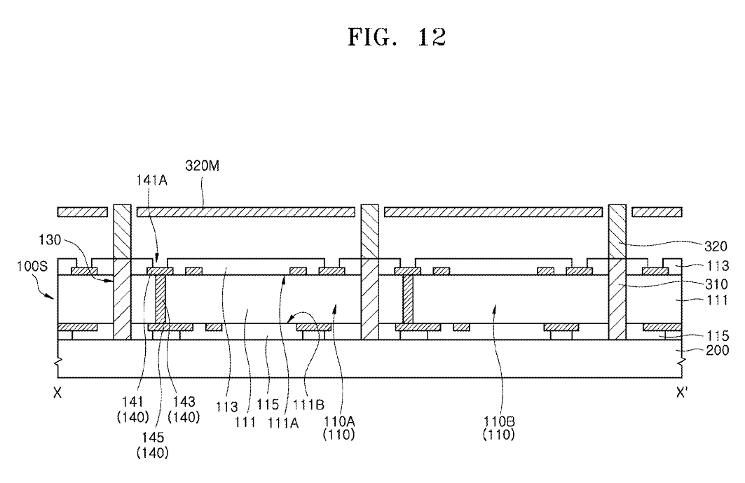

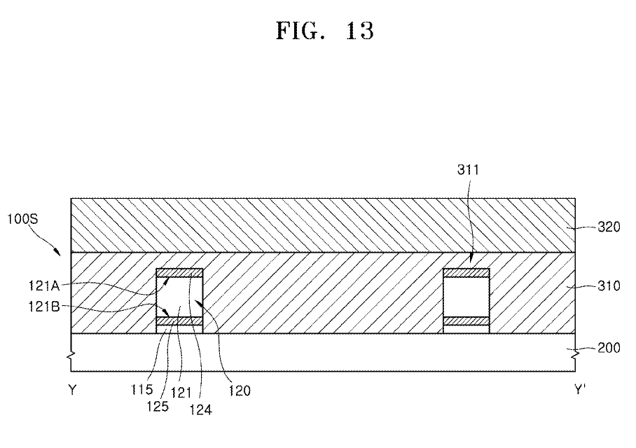

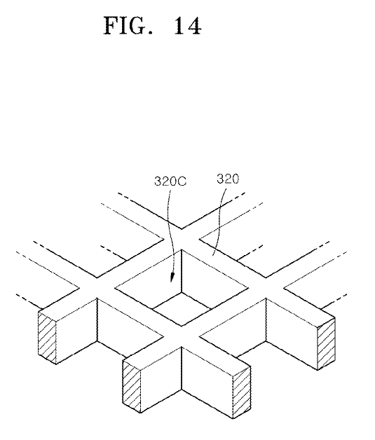

FIGS. 12, 13 and 14 illustrate a step of forming a second or upper side shielding part 320 protruding from a top surface of the package substrate strip 100S. FIG. 12 is a cross-sectional view taken along a line X-X′ of FIG. 1, and FIG. 13 is a cross-sectional view taken along a line Y-Y′ of FIG. 1. In addition, FIG. 14 is a perspective view illustrating a portion of the second side shielding part 320.

As illustrated in FIGS. 12, 13 and 14, the second side shielding part 320 may be formed to upwardly extend from the first side shielding part 310 to protrude from the package substrate strip 100S. The second side shielding part 320 may be formed of a conductive material having an EMI shielding function. The second side shielding part 320 may be formed to leave the chip mounting regions 110 exposed and to have a shape of a wall protruding from the package substrate strip 100S. The second side shielding part 320 may be formed to extend along borders of the chip mounting regions 110 when viewed from a plan view. That is, the second side shielding part 320 may have a grid shape to leave the chip mounting regions 110 exposed, as illustrated in FIG. 14. Accordingly, the second side shielding part 320 may be formed to provide and define cavities 320C on the chip mounting regions 110. Thus, the chip mounting regions 110 may remain exposed by the cavities 320C, respectively.

As illustrated in FIG. 13, the second side shielding part 320 may be formed to vertically overlap with the first side shielding part 310 and overlap with at least portions the bridge regions 120 of the package substrate strip 100S. That is, the second side shielding part 320 may be formed to cover the bridge regions 120. Since the bridge regions 120 are disposed to horizontally penetrate the first side shielding part 310, the chip mounting regions 110 may not be perfectly shielded in a horizontal direction due to the presence of the bridge regions 120. In contrast, the second side shielding part 320 may be formed to completely surround edges of the cavities (320C of FIG. 14). Thus, each of the cavities 320C may be completely shielded by the second side shielding part 320 in a horizontal direction.

In some embodiments, as illustrated in FIG. 12, a second conductive adhesive may be coated on the package substrate strip 100S using a stencil mask 320M that leaves the first side shielding part 310 selectively exposed. As a result, the second conductive adhesive may be selectively coated on the stencil mask 320M to coat the first side shielding part 310. Accordingly, the coated second conductive adhesive may vertically overlap with the first side shielding part 310 to upwardly protrude from the package substrate strip 100S. The coated second conductive adhesive may then be cured to form the second side shielding part 320 having a solid phase. Thus, the second side shielding part 320 may be formed to be vertically aligned with the first side shielding part 310. The second conductive adhesive may be a paste material having a viscosity which is higher than a viscosity of the first conductive adhesive. Thus, the coated second conductive adhesive may not fall down even without any molding patterns supporting the coated second conductive adhesive. The second conductive adhesive may be a paste material that is obtained by dispersing conductive particles in a resin material. Silver particles may be used as the conductive particles, and an epoxy resin material may be used as a matrix material of the resin material. The viscosity of the second conductive adhesive may be appropriately adjusted by controlling a composition ratio of the epoxy resin material as well as a size and a content of the conductive particles.

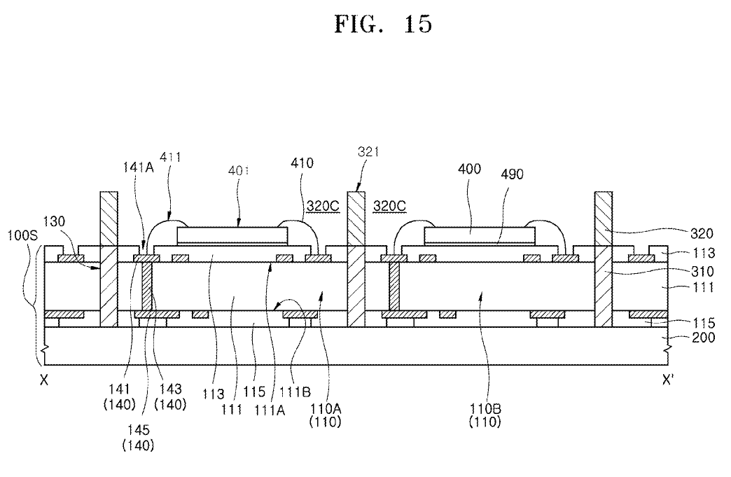

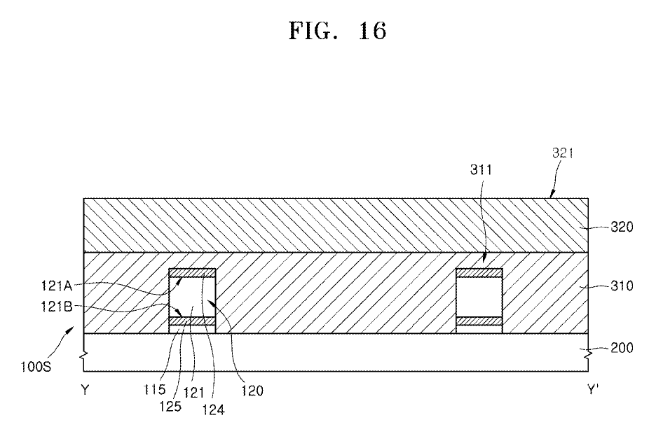

FIGS. 15 and 16 illustrate a step of mounting semiconductor chips 400 on the chip mounting regions 110. FIG. 15 is a cross-sectional view taken along a line X-X′ of FIG. 1, and FIG. 16 is a cross-sectional view taken along a line Y-Y′ of FIG. 1.

As illustrated in FIGS. 15 and 16, the semiconductor chips 400 may be respectively mounted on the chip mounting regions 110 exposed by the cavities 320C that are provided by the second side shielding part 320. The semiconductor chips 400 may be electrically connected to the chip mounting regions 110, respectively. Specifically, connection members such as bonding wires 410 may be formed to electrically connect the semiconductor chips 400 to the remaining exposed portions 141A (corresponding to landing pads) of the first trace patterns 141. The semiconductor chips 400 may be attached to the first dielectric layer 113 of the chip mounting regions 110 using an adhesive layer 490. In some embodiments, the semiconductor chips 400 may be electrically connected to the chip mounting regions 110 using bumps instead of the bonding wires 410.

A top surface 321 of the second side shielding part 320 may be located at a level which is higher than top surfaces 401 of the semiconductor chips 400. The top surface 321 of the second side shielding part 320 may be located at a level which is higher than topmost portions 411 of the bonding wires 410. Thus, the semiconductor chip 400 and the bonding wires 410 disposed in each cavity 320C may be completely surrounded by the second side shielding part 320. As a result, the semiconductor chip 400 and the bonding wires 410 disposed in each cavity 320C may be fully shielded and isolated from the other semiconductor chips 400 by the second side shielding part 320. Although FIG. 15 illustrates an example in which only one of the semiconductor chips 400 is located in each cavity 320C, the present disclosure is not limited thereto. For example, in some embodiments, two or more semiconductor chips may be disposed on each of the semiconductor chips 400 in each of the cavity 320C.

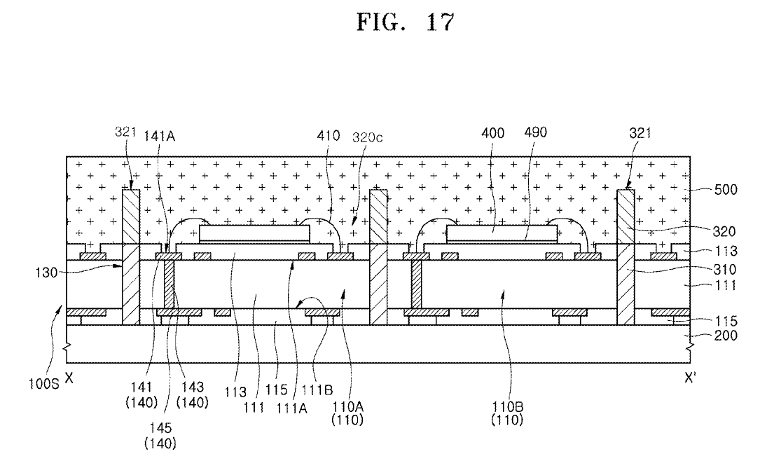

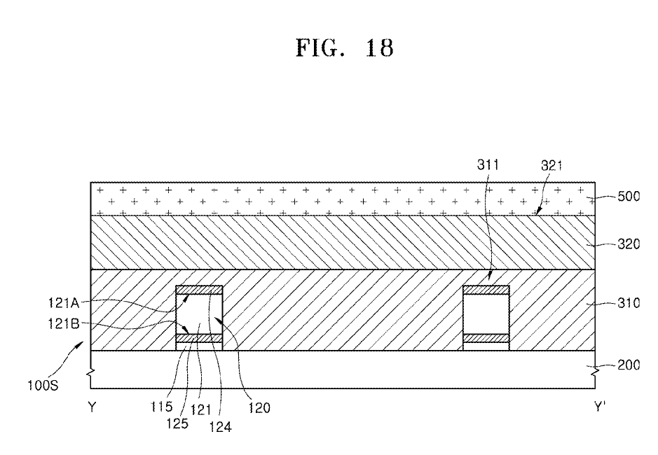

FIGS. 17 and 18 illustrate a step of forming a molding layer 500. FIG. 17 is a cross-sectional view taken along a line X-X′ of FIG. 1, and FIG. 18 is a cross-sectional view taken along a line Y-Y′ of FIG. 1.

As illustrated in FIGS. 17 and 18, the molding layer 500 may be formed to cover the second side shielding part 320, the semiconductor chips 400, the bonding wires 410 and the chip mounting regions 110. The molding layer 500 may be formed of an epoxy molding compound (EMC) material using a molding process. The molding layer 500 may be formed of a dielectric layer to insulate and protect the semiconductor chips 400 and the bonding wires 410. The molding layer 500 may be formed to fully fill the cavities (320C of FIG. 15) which are provided by the second side shielding part 320 having a grid shape. The molding layer 500 may be formed to have a sufficient thickness to fully cover the top surface 321 of the second side shielding part 320. The molding layer 500 may be formed to fully cover an entire top surface of the package substrate strip 100S. The molding layer 500, covering all of the semiconductor chips 400 and an entire top surface of the package substrate strip 100S, may be formed using a single molding process at a time. Thus, this embodiment may be suitable for mass production of the semiconductor packages.

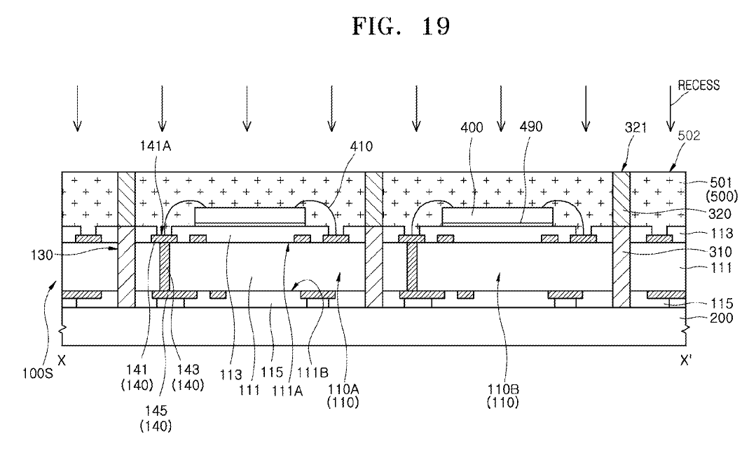

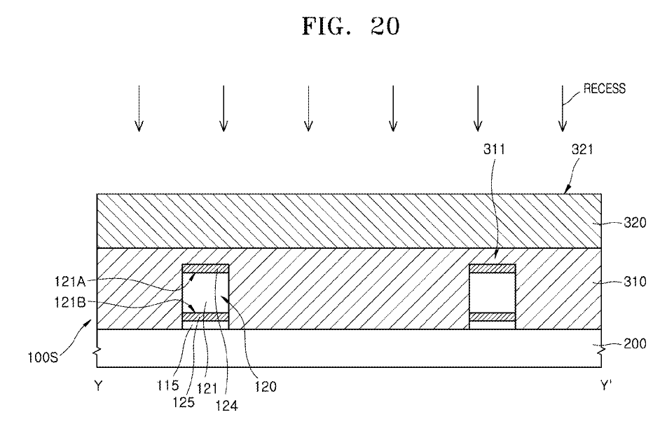

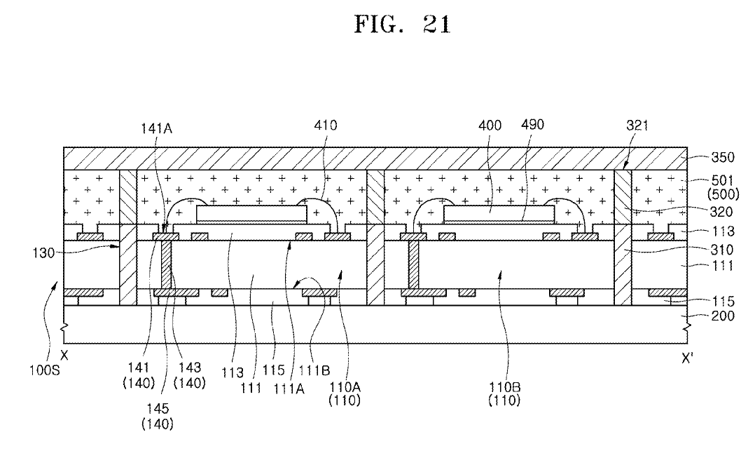

FIGS. 19 and 20 illustrate a step of forming mold patterns 501 exposing a portion of the second side shielding part 320. FIG. 19 is a cross-sectional view taken along a line X-X′ of FIG. 1, and FIG. 20 is a cross-sectional view taken along a line Y-Y′ of FIG. 1.

As illustrated in FIGS. 19 and 20, the molding layer (500 of FIGS. 17 and 18) may be recessed to reduce a thickness of the molding layer 500 and to form mold patterns 501 on the package substrate strip 100s having recessed surfaces 502. The molding layer 500 may be recessed to expose a portion of the second side shielding part 320, for example, the top surface 321 of the second side shielding part 320. The mold patterns 501 may be formed by applying a grinding process to a top surface of the molding layer 500. The molding layer 500 may be separated into the mold patterns 501 by recessing the molding layer 500 until the top surface 321 of the second side shielding part 320 is exposed. That is, the mold patterns 501 may be formed to fill the cavities 320C provided by the second side shielding part 320 having a grid shape. The recessed surfaces 502 of the mold patterns 501 may be substantially coplanar with each other to have a flat profile.

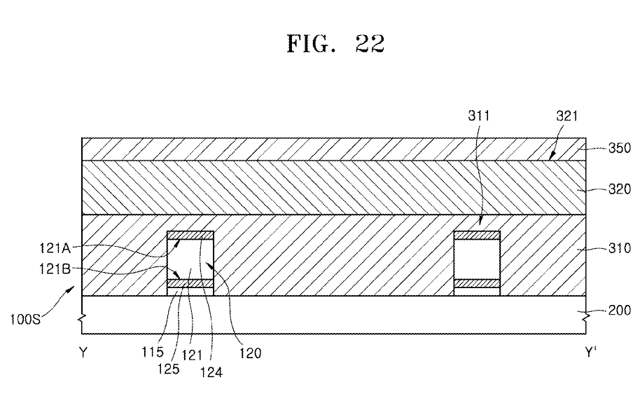

FIGS. 21 and 22 illustrate a step of forming a top shielding part 350. FIG. 21 is a cross-sectional view taken along a line X-X′ of FIG. 1, and FIG. 22 is a cross-sectional view taken along a line Y-Y′ of FIG. 1.

As illustrated in FIGS. 21 and 22, the top shielding part 350 may be formed to cover the mold patterns 501. The top shielding part 350 may be formed to contact the top surface 321 of the second side shielding part 320 which is exposed by the mold patterns 501. Accordingly, the top shielding part 350 may be electrically connected to the second side shielding part 320. The first and second side shielding parts 310 and 320 and the top shielding part 350 may constitute an EMI shielding cage. The EMI shielding cage may further include an array of the edge shielding pillars 150 illustrated in FIG. 4. The EMI shielding cage may shield the semiconductor chips 400 on the chip mounting regions 110 from EMI.

The top shielding part 350 may be formed by depositing a conductive layer to cover the mold patterns 501 and the second side shielding part 320 using a sputtering process or a chemical vapor deposition (CVD) process. Alternatively, the top shielding part 350 may be formed using a spray process or an electroplating process. The top shielding part 350 may be formed on the top surfaces of the mold patterns 501 and the second side shielding part 320 at the same time using a single process. Thus, the throughput of a fabrication process may be improved, as compared with a case that the top shielding part 350 is individually formed on each of the mold patterns 501 after the chip mounting regions 110 are separated from each other. In addition, the top shielding part 350 may be formed to cover the flat top surfaces of the mold patterns 501 before the chip mounting regions 110 are separated from each other. Thus, the top shielding part 350 may be reliably and quickly formed, as compared to a conductive layer for the EMI shielding cage individually formed to cover a top surface and sidewalls of each semiconductor package after the chip mounting regions 110 are separated from each other.

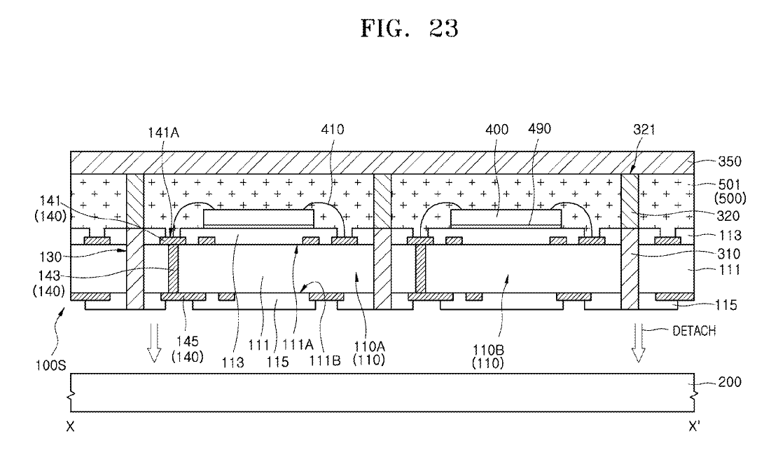

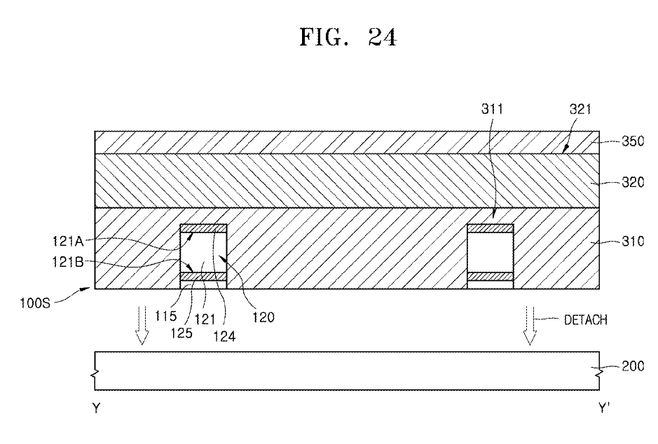

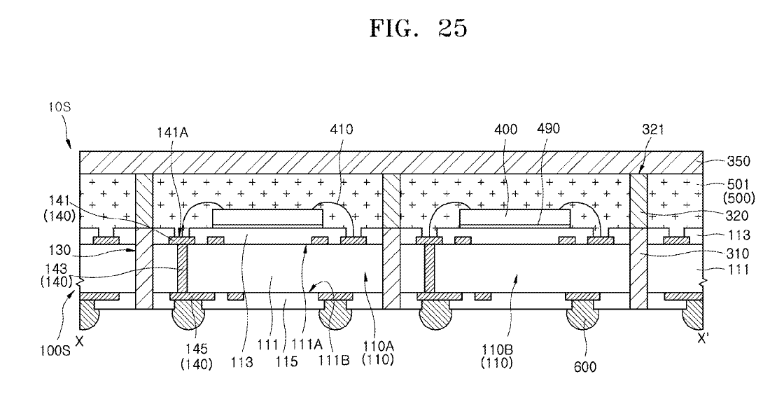

FIGS. 23 and 24 illustrate a step of detaching the carrier 200 from the package substrate strip 100S. FIG. 23 is a cross-sectional view taken along a line X-X′ of FIG. 1, and FIG. 24 is a cross-sectional view taken along a line Y-Y′ of FIG. 1.

As illustrated in FIGS. 23 and 24, the carrier 200 may be detached and removed from the package substrate strip 100S. The processes of forming the first and second side shielding parts 310 and 320, mounting the semiconductor chips 400, forming the mold patterns 501, and forming the top shielding part 350 may be applied to the package substrate strip 100S supported by the carrier 200. The carrier 200 may be detached from the package substrate strip 100S before the package substrate strip 100S including the top shielding part 350 is cut and before solder balls used as connection terminals are attached to the package substrate strip 100S.

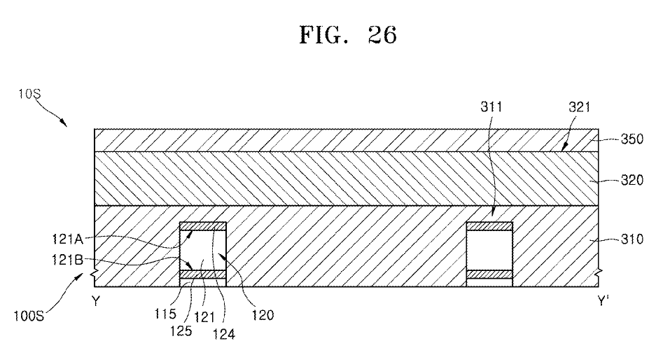

FIGS. 25 and 26 illustrate a step of attaching external connection terminals 600 to the package substrate strip 100S. FIG. 25 is a cross-sectional view taken along a line X-X′ of FIG. 1, and FIG. 26 is a cross-sectional view taken along a line Y-Y′ of FIG. 1.

As illustrated in FIGS. 25 and 26, the external connection terminals 600 may be attached to the exposed portions of the second trace patterns 145, respectively. The external connection terminals 600 may be solder balls. The external connection terminals 600 may be simultaneously attached to the exposed portions of the second trace patterns 145 of the package substrate strip 100S using a single step of a ball mounting process. As a result of formation of the external connection terminals 600, a semiconductor package structure 10S may be formed on the package substrate strip 100S. The semiconductor package structure 10S may include the first side shielding part 310 penetrating the package substrate strip 100S along the periphery of the chip mounting regions 110 to shield the chip mounting regions 110, the second side shielding part 320 stacked on the first side shielding part 310 to shield the semiconductor chips 400 mounted on the chip mounting regions 110, the mold patterns 501 filling the cavities 320C provided by the second side shielding part 320 to protect the semiconductor chips 400, and the top shielding part 350 covering top surfaces of the mold patterns 501 and being electrically connected to the second side shielding part 320. The semiconductor package structure 10S may be formed to include a plurality of unit semiconductor packages.

Since the chip mounting regions 110 are connected and fixed to each other by the bridge regions 120, the bridge regions 120 may prevent the chip mounting regions 110 from being twisted or distorted. If at least one of the chip mounting regions 110 is twisted or distorted so that a position of the chip mounting region 110 changes, it may be difficult to accurately attach the external connection terminals 600 to the exposed portions of the second trace patterns 145. However, according to the embodiments, the chip mounting regions 110 may be still connected and fixed to each other by the bridge regions 120 even while the external connection terminals 600 are attached to the exposed portions of the second trace patterns 145. Thus, no process failures may occur during a process for attaching the external connection terminals 600 to the exposed portions of the second trace patterns 145.

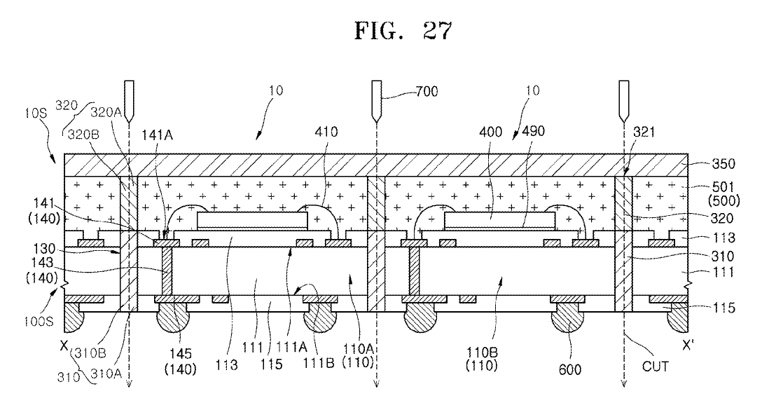

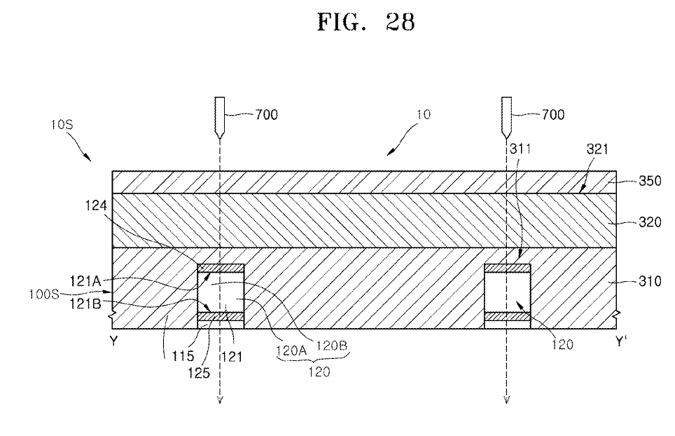

FIGS. 27 and 28 illustrate a step of separating a plurality of semiconductor packages from each other. FIG. 27 is a cross-sectional view taken along a line X-X′ of FIG. 1, and FIG. 28 is a cross-sectional view taken along a line Y-Y′ of FIG. 1.

As illustrated in FIGS. 27 and 28, a singulation process may be used to separate the plurality of semiconductor packages from each other. For example, the package substrate strip 100S including the plurality of semiconductor packages may be cut with a sawing blade 700 moving along a central region of the first and second side shielding parts 310 and 320 to separate the plurality of semiconductor packages from each other, such that each of the unit semiconductor packages includes any one of the chip mounting regions 110. Further, each of the unit semiconductor packages includes at least two adjacent chip mounting regions 110 and at least a portion of the second side shielding part 320 disposed between the at least two adjacent chip mounting regions 110 constituting each of the unit semiconductor packages. The singulation process for separating the plurality of semiconductor packages from each other may be performed using a laser beam instead of the sawing blade 700.

The sawing blade 700 may be disposed on and cut the top shielding part 350 and may be aligned with a central region of the second side shielding part 320. The sawing blade 700 may cut the second side shielding part 320 in two portions to provide a first half of second side shielding part 320A and a second half of second side shielding part 320B separated from each other. Subsequently, the sawing blade 700 may also cut the first side shielding part 310 in two portions to provide a first half of first side shielding part 310A and a second half of first side shielding part 310B separated from each other. While the first side shielding part 310 is cut by the sawing blade 700, each of the bridge regions 120 may also be separated into two portions to provide a first half bride region 120A and a second half bride region 120B separated from each other. As a result, the plurality of semiconductor packages may be separated from each other.

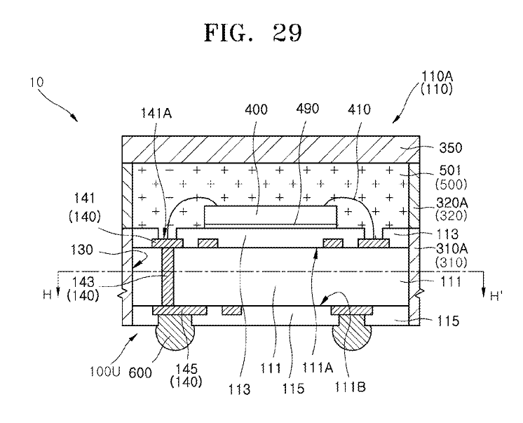

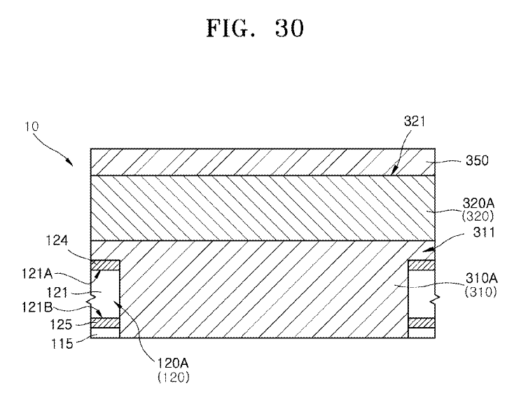

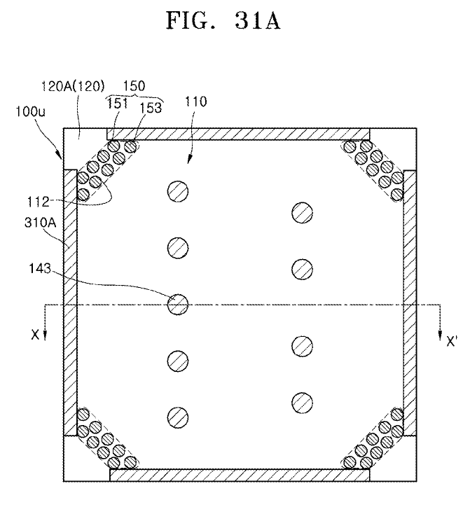

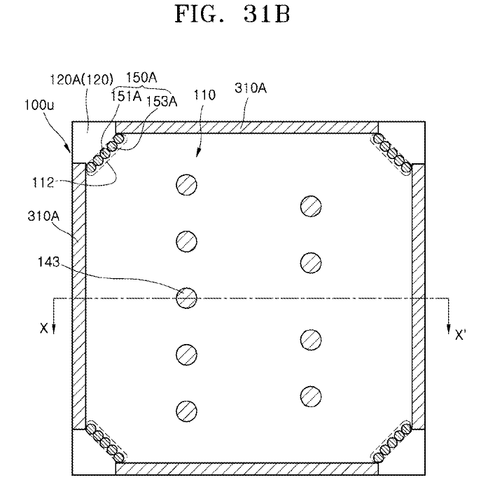

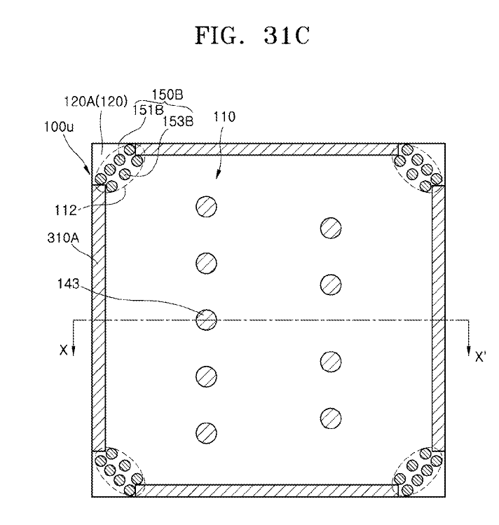

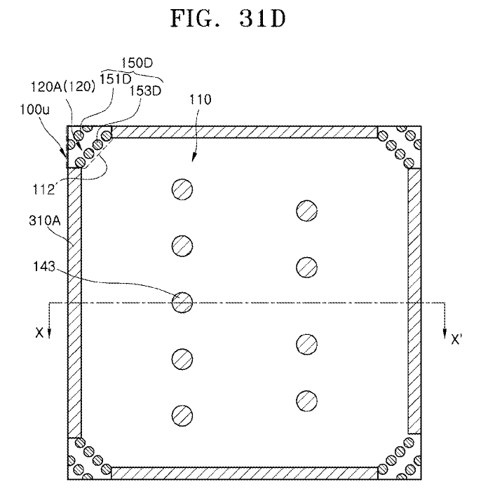

FIGS. 29 and 30 illustrate a unit semiconductor package 10 corresponding to any one of the plurality of semiconductor packages separated from each other. FIG. 29 is a cross-sectional view of the unit semiconductor package 10 taken along the same cutting line as a line X-X′ of FIG. 1, and FIG. 30 is a cross-sectional view of the unit semiconductor package 10 taken along the same cutting line as a line Y-Y′ of FIG. 1. FIGS. 31A, 31B, 31C and 31D are various plan views of a unit package substrate 100U taken along a line H-H′ of FIG. 29.

As illustrated in FIGS. 29 and 30, the unit semiconductor package 10 may be configured so that the first half of the first side shielding part 310A shields the unit package substrate 100U. The first half of second side shielding part 320A may surround sidewalls of the mold pattern 501 to shield the semiconductor chip 400 mounted on the unit package substrate 100U from EMI. The top shielding part 350 may cover the top surface of the mold pattern 501 to additionally shield the semiconductor chip 400.

As illustrated in FIG. 31A, the unit package substrate 100U may have a rectangular shape in a plan view, and the first half of first side shielding part 310A may be disposed in four edges of the unit package substrate 100U to define the chip mounting region 110. The first half of the first side shielding part 310A may be disposed to surround the chip mounting region 110, and the first half bridge regions 120A may be located at four corners of the unit package substrate 100U. Outer sidewalls of the first half bridge regions 120A may be exposed. Thus, since electromagnetic waves or high frequency noises traveling in a horizontal direction can be propagated through the first half bridge regions 120A, the chip mounting region 110 may possibly not be shielded from an EMI phenomenon. However, according to an embodiment, the edge shielding pillars 150 may be vertically disposed to penetrate each of the bridge regions 120 including the first half bridge regions 120A in order to prevent electromagnetic waves or high frequency noises travelling in a horizontal direction from being propagated through the first half bridge regions 120A.

As illustrated in FIG. 4, the edge shielding pillars 150 may penetrate the first half bridge regions 120A to connect the first trace patterns 141S on a top surface of the package substrate body 122 (corresponding to the first half bridge regions 120A) to the second trace patterns 145S on a bottom surface of the package substrate body 122. As illustrated in FIG. 30, the first bridge trace patterns 124 in the first half bridge regions 120A may be in contact with and connected to the extensions 311 of the first half of first side shielding part 310A, and the first bridge trace patterns 124 may be electrically connected to a ground terminal through the first trace patterns (141S of FIG. 4), the edge shielding pillars (150 of FIG. 4), and the second trace patterns (145S of FIG. 4).

The edge shielding pillars 150 illustrated in FIG. 31A may include the first edge shielding pillars 151 and the second edge shielding pillars 153 which are disposed in each edge corner of the chip mounting region 110 adjacent to the bridge region 120A, as described with reference to FIG. 5.

Referring to FIG. 31B, the first edge shielding pillars 151A and the second edge shielding pillars 153A may be alternately arrayed in one column to be in contact with each other in each edge corner of the chip mounting region 110 to constitute the edge shielding wall 150A, as described with reference to FIG. 6. The edge shielding wall 150A may be connected to the first side shielding part 310A in a horizontal direction.

Referring to FIG. 31C, the first edge shielding pillars 151B among the edge shielding pillars 150B may be disposed in the bridge region 120A, and the second edge shielding pillars 153B among the edge shielding pillars 150B may be disposed in the chip mounting region 110 adjacent to the bridge region 120A.

Referring to FIG. 31D, all of edge shielding pillars 150D may be disposed in the bridge region 120A. The edge shielding pillars 150D may include first edge shielding pillars 151D and second edge shielding pillars 153D. The second edge shielding pillars 153D may be disposed to be adjacent to the boundary portion 112, and the first edge shielding pillars 151D may be disposed to be further away from the boundary portion 112 than the second edge shielding pillars 153D. In such a case, some of the first edge shielding pillars 151D may be cut during the singulation process described with reference to FIGS. 27 and 28. Thus, some of the first edge shielding pillars 151D may be exposed at sidewalls of the bridge region 120A.

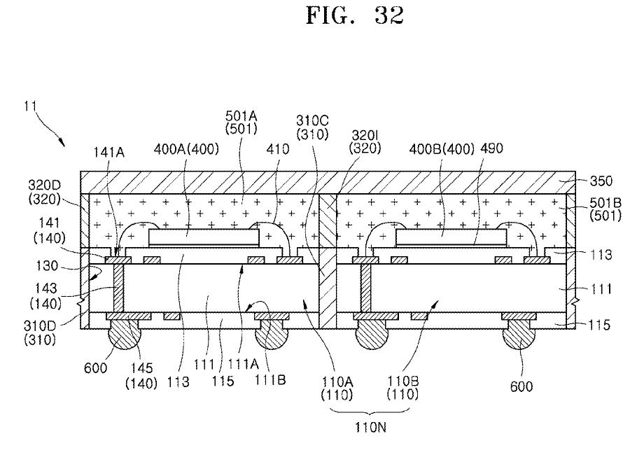

FIG. 32 is a cross-sectional view illustrating a unit semiconductor package 11 according to an embodiment. FIG. 32 is a cross-sectional view taken along a line X-X′ of FIG. 1.

As illustrated in FIG. 32, the unit semiconductor package 11 may include first and second chip mounting regions 110A and 110B which are adjacent to each other. The unit semiconductor package 11 may be singulated to include a structure having first outer side shielding parts 310D which surround outer sidewalls of a unit package substrate 110N to horizontally shield the first and second chip mounting regions 110A and 110B of the unit package substrate 110N. A first semiconductor chip 400A may be mounted on the first chip mounting region 110A, and a second semiconductor chip 400B may be mounted on the second chip mounting region 110B. Second outer side shielding parts 320D may surround outer sidewalls of a first mold pattern 501A and outer sidewalls of a second mold pattern 501B to horizontally shield the first and second semiconductor chips 400A and 400B. A second inner side shielding part 3201 may be disposed between the first mold pattern 501A and the second mold pattern 501B to prevent an EMI phenomenon between the first and second semiconductor chips 400A and 400B. A top shielding part 350 may be disposed to cover top surfaces of the second side shielding parts 320D and 3201 and the mold patterns 501A and 501B. A first inner side shielding part 310C may be disposed between the first chip mounting region 110A and the second chip mounting region 110B to prevent an EMI phenomenon between the first and second chip mounting regions 110A and 110B. In some embodiments, the first inner side shielding part 310C may be absent between the first and second chip mounting regions 110A and 110B.

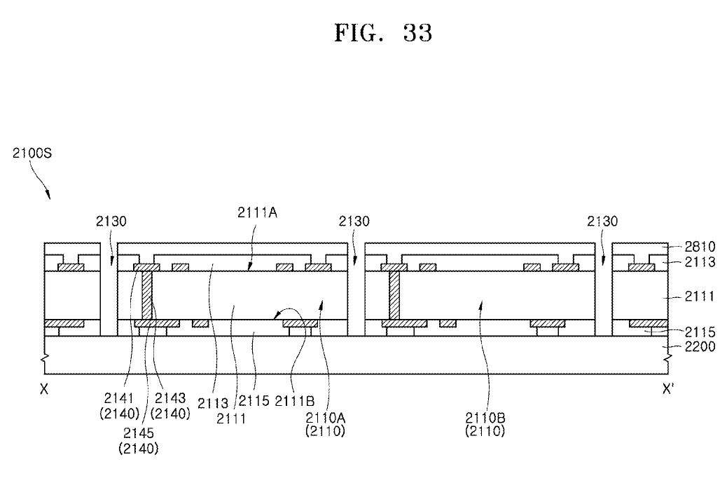

FIGS. 33 to 48 are cross-sectional views illustrating a method of fabricating semiconductor packages according to another embodiment and semiconductor packages fabricated thereby.

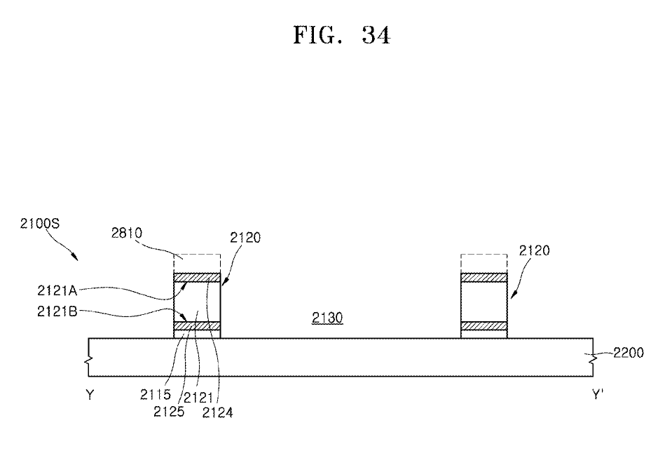

FIGS. 33 and 34 illustrate a step of forming a first mask 2810. FIG. 33 is a cross-sectional view taken along a line X-X′ of FIG. 1, and FIG. 34 is a cross-sectional view taken along a line Y-Y′ of FIG. 1.

As illustrated in FIGS. 33 and 34, a package substrate strip 2100S may be located over the carrier 2200 and may be attached and fixed to the carrier 2200 using a lamination process. The package substrate strip 2100S may have substantially the same configuration as the package substrate strip 100S described with reference to FIGS. 1 and 2. That is, the package substrate strip 2100S may include through slits 2130 disposed between and defining chip mounting regions 2110 (e.g., a first chip mounting region 2110A and a second chip mounting region 2110B) and may further include bridge regions 2120 connecting and fixing the chip mounting regions 2110 to each other. Each of the chip mounting regions 2110 may include a substrate body layer 2111, and a circuit interconnection structure 2140 which may be disposed on and in the body layer 2111. The circuit interconnection structure 2140 may include first trace patterns 2141, second trace patterns 2145, and internal trace patterns 2143. A first dielectric layer 2113 may be disposed on a first surface 2111A of the substrate body layer 2111, and a second dielectric layer 2115 may be disposed on a second surface 21118 of the substrate body layer 2111. Each of the bridge regions 2120 may include a bridge body layer 2121, a first bridge trace pattern 2124 disposed on a first surface 2121A of the bridge body layer 2121, and a second bridge trace pattern 2125 disposed on a second surface 21218 of the bridge body layer 2121 opposite to the first bridge trace pattern 2124. The first and second bridge trace patterns 2124 and 2125 may be grounded.

The first mask 2810 may be formed on a first surface 2111A of the substrate body layer 2111 to keep the through slits 2130 open and to leave the bridge regions 2120 exposed. The first mask 2810 may be formed to cover the chip mounting regions 2110. The first mask 2810 may be formed by attaching a dry film to the first dielectric layer 2113 using a lamination process, by selectively exposing predetermined regions of the dry film to an ultraviolet (UV) ray, and by developing the exposed dry film.

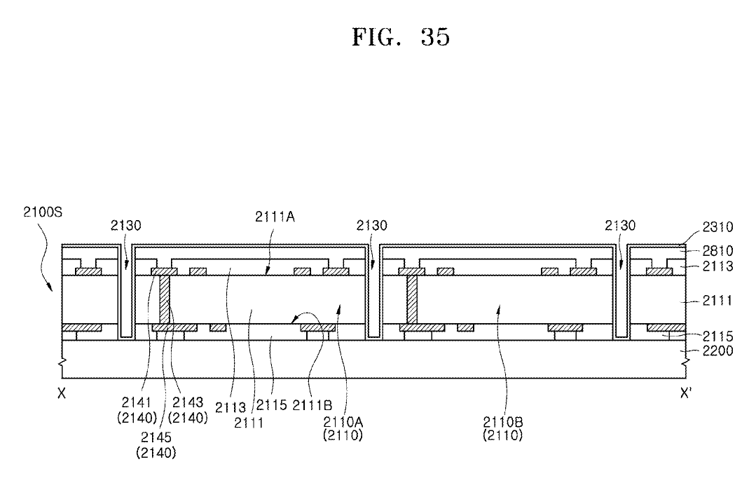

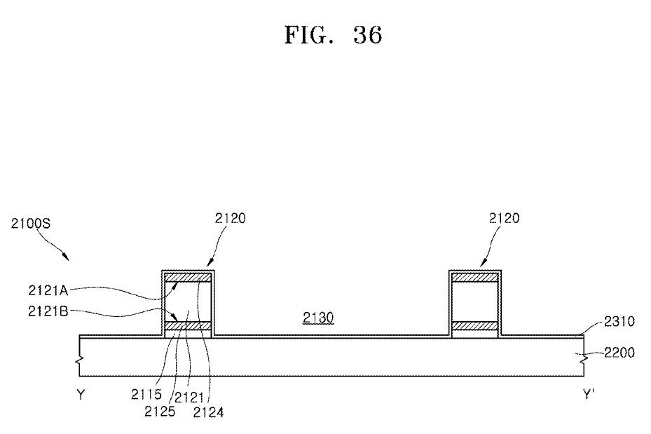

FIGS. 35 and 36 illustrate a step of forming a seed metal layer 2310. FIG. 35 is a cross-sectional view taken along a line X-X′ of FIG. 1, and FIG. 36 is a cross-sectional view taken along a line Y-Y′ of FIG. 1.

As illustrated in FIGS. 35 and 36, the seed metal layer 2310 may be formed on the first mask 2810 and in the through slits 2130. Thus, the seed metal layer 2310 may be formed to cover sidewalls of the through slits 2130 and portions of the carrier 2200 exposed by the through slits 2130. The seed metal layer 2310 may be formed to have the same profile as the through slits 2130. Accordingly, the seed metal layer 2310 may have concave surfaces in the through slits 2130. The seed metal layer 2310 may be formed to cover the first bridge trace patterns 2124 of the bridge regions 2120. The seed metal layer 2310 may be formed using an electroless plating process or a deposition process such as a sputtering process. The seed metal layer 2310 may be formed to include a copper material.

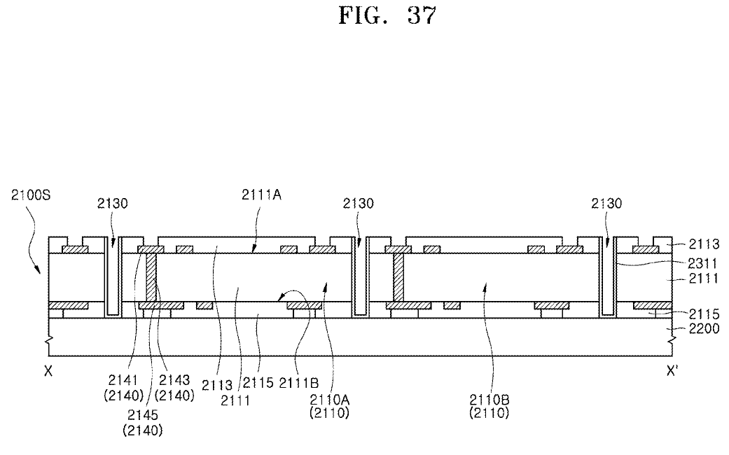

FIGS. 37 and 38 illustrate a step of forming seed metal patterns 2311. FIG. 37 is a cross-sectional view taken along a line X-X′ of FIG. 1, and FIG. 38 is a cross-sectional view taken along a line Y-Y′ of FIG. 1.

As illustrated in FIGS. 37 and 38, the first mask 2810 may be selectively removed from the package substrate strip 2100S. While the first mask 2810 is removed, portions of the seed metal layer 2310 disposed on the first mask 2810 may also be removed to selectively leave the seed metal patterns 2311 at least on inner walls of the through slits 2130 and on the bridge regions 2120.

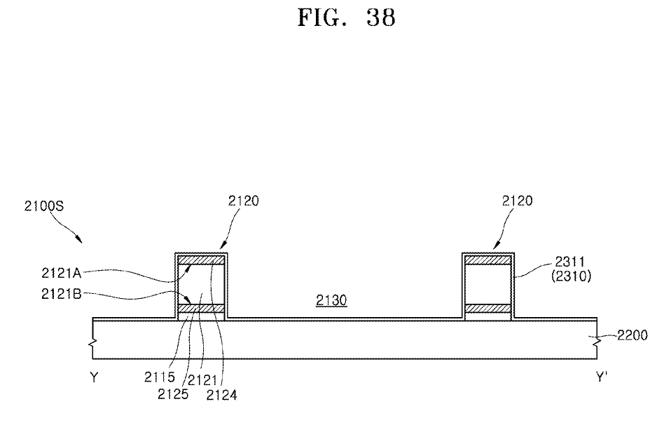

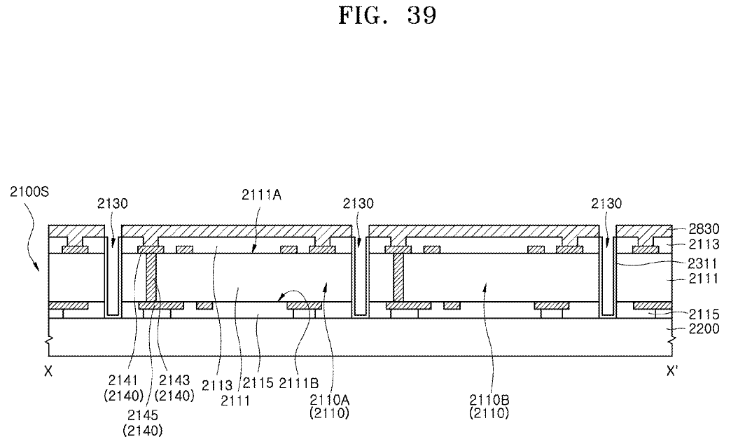

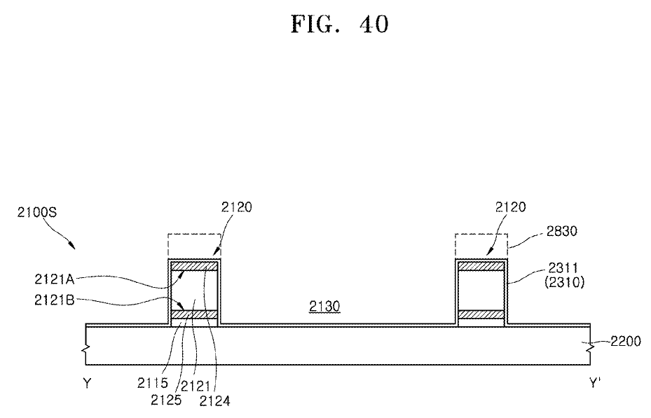

FIGS. 39 and 40 illustrate a step of forming a second mask 2830. FIG. 39 is a cross-sectional view taken along a line X-X′ of FIG. 1, and FIG. 40 is a cross-sectional view taken along a line Y-Y′ of FIG. 1.

As illustrated in FIGS. 39 and 40, the second mask 2830 may be formed on the first surface 2111A of the substrate body layer 2111 and leave the seed metal patterns 2311 exposed. The second mask 2830 may be formed to cover the chip mounting regions 2110. The second mask 2830 may be formed by attaching a dry film to the first dielectric layer 2113 using a lamination process, by selectively exposing predetermined regions of the dry film to an ultraviolet (UV) ray, and by developing the exposed dry film.

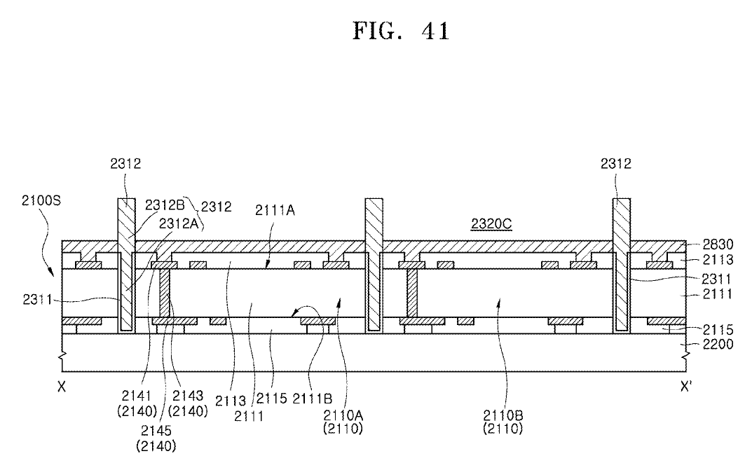

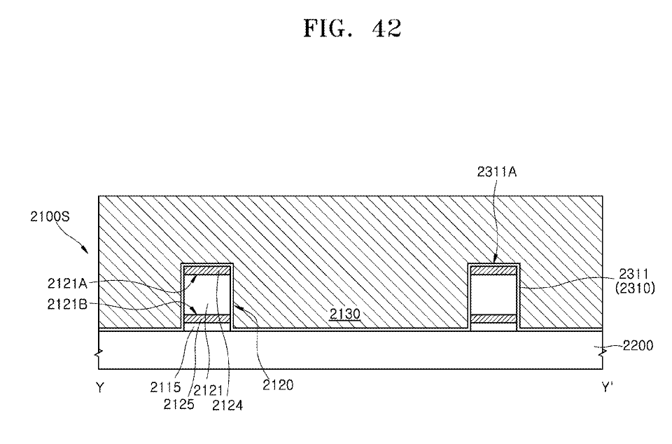

FIGS. 41 and 42 illustrate a step of forming a side shielding part 2312. FIG. 41 is a cross-sectional view taken along a line X-X′ of FIG. 1, and FIG. 42 is a cross-sectional view taken along a line Y-Y′ of FIG. 1.

As illustrated in FIGS. 41 and 42, an electroplating process may be performed by supplying electrolyte onto the seed metal patterns 2311 left exposed by the second mask 2830 to form the side shielding part 2312 and by forcing a current into the electrolyte using the seed metal patterns 2311 as cathodes. The seed metal patterns 2311 in the through slits 2130 may be connected to each other through overlap portions (2111A of FIG. 41) of the seed metal patterns 2311 remaining on the bridge regions 2120, as illustrated in FIG. 42. Thus, even though only one among the seed metal patterns 2311 located on the package substrate strip 2100S is connected to a cathode terminal, all of the seed metal patterns 2311 may be electrically connected to the cathode terminal to act as cathodes. As a result, a plating layer may be grown on the seed metal patterns 2311 using an electroplating process. If a process time of the electroplating process increases, the plating layer may be grown to form the side shielding part 2312 protruding from the package substrate strip 2100S and the second mask 2830.

While the electroplating process is performed, a step of forming the seed metal patterns 2311 may be omitted. For example, after the seed metal layer 2310 is formed (see FIGS. 35 and 36), a step of patterning the seed metal layer 2310 illustrated in FIGS. 37 and 38 may be omitted. After the seed metal layer 2310 is formed, the second mask 2830 illustrated in FIGS. 39 and 40 may be formed on the seed metal layer 2310 without removal of the first mask 2810. In such a case, even though the seed metal layer 2310 is partially covered with the second mask 2830, portions of the seed metal layer 2310 corresponding to the seed metal patterns 2311 may be left exposed by the second mask 2830. Subsequently, an electroplating process may be performed to form the side shielding part 2312, as illustrated in FIGS. 41 and 42. The second mask 2830 and the first mask 2810 may then be sequentially removed to selectively remove portions of the seed metal layer 2310 which are left exposed by the side shielding part 2312.

The side shielding part 2312 may be formed to include a first or lower side shielding part 2312A filling the through slits 2130 and a second or upper side shielding part 2312B protruding from the chip mounting regions 2110. The first side shielding part 2312A may correspond to the first side shielding part 310 of FIG. 12, and the second side shielding part 2312B may correspond to the second side shielding part 320 of FIG. 12. The first side shielding part 2312A may be formed to cover sidewalls of the chip mounting regions 2110 like the first side shielding part 310, and the second side shielding part 2312B may be formed to have a grid shape like the second side shielding part 320 (see FIG. 14). Thus, the second side shielding part 2312B may be formed to provide cavities 2320C on the chip mounting regions 2110.

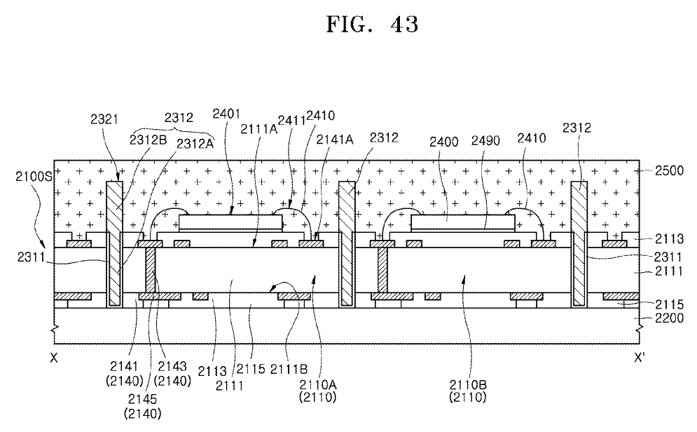

FIGS. 43 and 44 illustrate a step of forming a molding layer 2500. FIG. 43 is a cross-sectional view taken along a line X-X′ of FIG. 1, and FIG. 44 is a cross-sectional view taken along a line Y-Y′ of FIG. 1.

As illustrated in FIGS. 43 and 44, semiconductor chips 2400 may be disposed in the cavities 2320C provided by the side shielding part 2312. The semiconductor chips 2400 may be electrically connected to landing pads 2141A of the first trace patterns 2141 in the chip mounting regions 2110 through connection members such as bonding wires 2410. The semiconductor chips 2400 may be attached to the first dielectric layer 2113 on the chip mounting regions 2110 using an adhesive layer 2490.

A top surface 2321 of the side shielding part 2312 may be located at a level which is higher than top surfaces 2401 of the semiconductor chips 2400. The top surface 2321 of the side shielding part 2312 may be located at a level which is higher than topmost portions 2411 of the bonding wires 2410. Thus, the semiconductor chip 2400 and the bonding wires 2410 disposed in each cavity 2320C may be completely surrounded by the second side shielding part 2312B. As a result, the semiconductor chip 2400 and the bonding wires 2410 disposed in each cavity 2320C (see FIG. 41) may be fully shielded and isolated from the other semiconductor chips 2400 by the second side shielding part 2312B in a horizontal direction. The molding layer 2500 may be formed to cover the side shielding part 2312, the semiconductor chips 2400, the bonding wires 2410, and the chip mounting regions 2110. The molding layer 2500 may be formed to fully fill the cavities 2320C which are provided by the side shielding part 2312 having a grid shape.

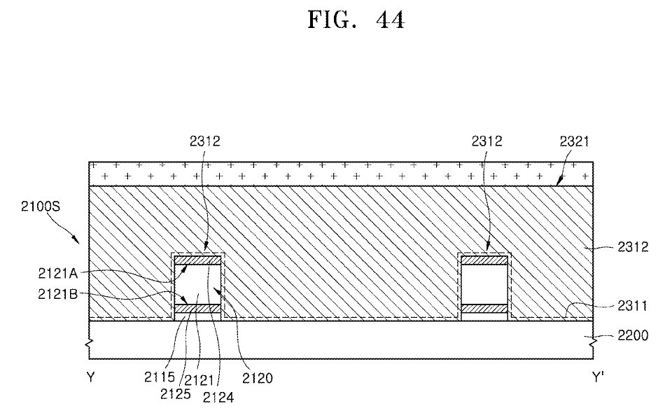

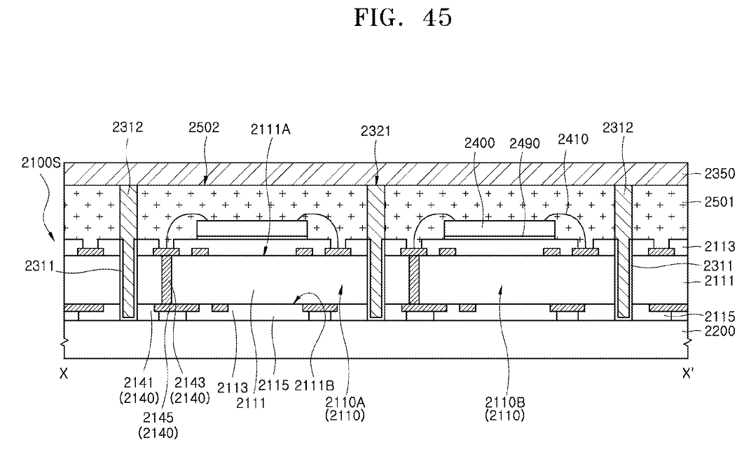

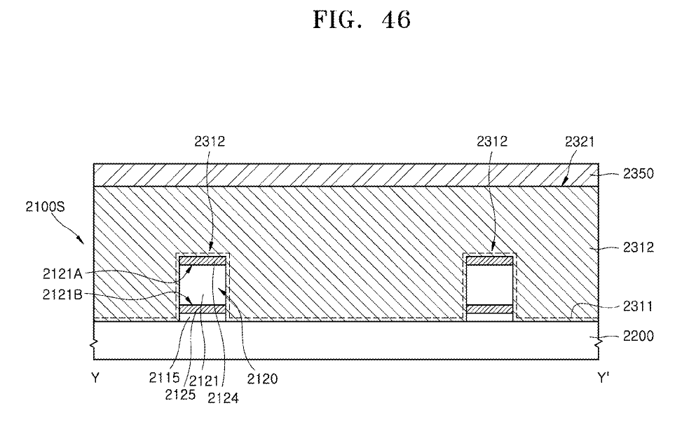

FIGS. 45 and 46 illustrate a step of forming a top shielding part 2350. FIG. 45 is a cross-sectional view taken along a line X-X′ of FIG. 1, and FIG. 46 is a cross-sectional view taken along a line Y-Y′ of FIG. 1.

As illustrated in FIGS. 45 and 46, the molding layer 2500 may be recessed to form mold patterns 2501 having recessed surfaces 2502. The molding layer 2500 may be recessed to expose a portion of the side shielding part 2312, for example, the top surface 2321 of the side shielding part 2312. The molding layer 2500 may be separated into the mold patterns 2501 by recessing the molding layer 2500 until the top surface 2321 of the side shielding part 2312 is exposed. That is, the mold patterns 2501 may be formed to fill the cavities 2320C provided by the side shielding part 2312 having a grid shape. A top shielding part 2350 may be formed to cover the mold patterns 2501. The top shielding part 2350 may be formed to contact the top surface 2321 of the side shielding part 2312 which is exposed by the mold patterns 2501. Accordingly, the top shielding part 2350 may be electrically connected to a side shielding part 2312. The side shielding part 2312 and the top shielding part 2350 may constitute an EMI shielding cage. The EMI shielding cage may further include the array of the edge shielding pillars 150 illustrated in FIG. 4. The EMI shielding cage may shield the semiconductor chips 2400 in the chip mounting regions 2110 from EMI.

FIG. 47 illustrates a step of attaching external connection terminals 2600. FIG. 47 is a cross-sectional view taken along a line X-X′ of FIG. 1.

As illustrated in FIG. 47, the carrier 2200 may be detached and removed from the package substrate strip 2100S. The external connection terminals 2600 may be attached to exposed portions of the second trace patterns 2145 of the package substrate strip 2100S, respectively. The external connection terminals 2600 may be solder balls. The external connection terminals 2600 may be simultaneously attached to the exposed portions of the second trace patterns 2145 of the package substrate strip 2100S using a single step of ball mounting process. As a result of formation of the external connection terminals 2600, a plurality of semiconductor packages may be formed on the package substrate strip 2100S. The plurality of semiconductor packages may be separated from each other using a singulation process. The plurality of semiconductor packages may be separated from each other so that each semiconductor package includes one of the chip mounting regions 2110.

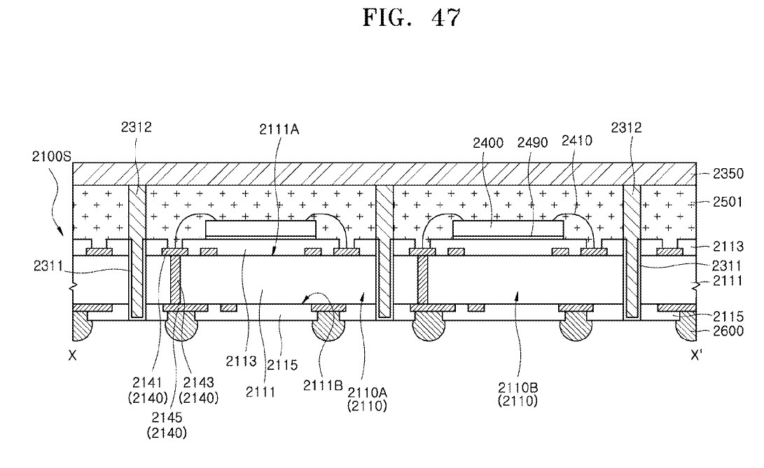

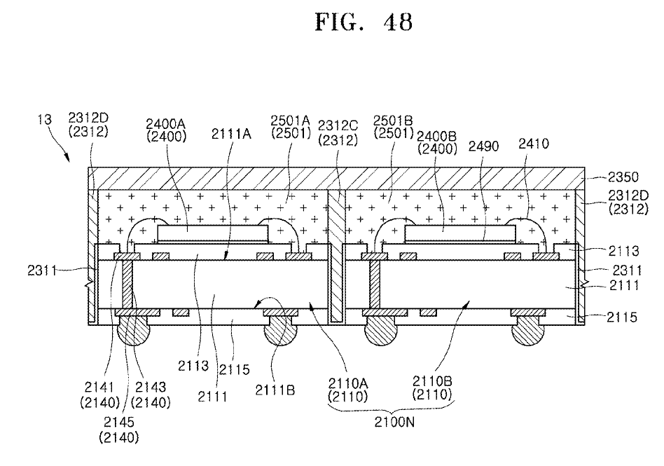

FIG. 48 illustrates a unit semiconductor package 13 according to an embodiment. FIG. 48 is a cross-sectional view taken along a line X-X′ of FIG. 1.

As illustrated in FIG. 48, the unit semiconductor package 13 may be singulated to include first and second chip mounting regions 2110A and 2110B which are adjacent to each other. The unit semiconductor package 13 may be singulated to include a structure having outer side shielding parts 2312D which surrounds outer sidewalls of a unit package substrate 2100N to horizontally shield the unit package substrate 2100N. A first semiconductor chip 2400A may be mounted on the first chip mounting region 2110A, and a second semiconductor chip 2400B may be mounted on the second chip mounting region 2110B. The outer side shielding parts 2312D may surround outer sidewalls of a first mold pattern 2501A and outer sidewalls of a second mold pattern 2501B to horizontally shield the first and second semiconductor chips 2400A and 2400B. An inner side shielding part 2312C may be disposed between the first mold pattern 2501A and the second mold pattern 2501B to prevent an EMI phenomenon between the first and second semiconductor chips 2400A and 2400B. A top shielding part 2350 may be disposed to cover top surfaces of the side shielding parts 2312D and 2312C and the mold patterns 2501A and 2501B. The inner side shielding part 2312C may extend into an interface between the first chip mounting region 2110A and the second chip mounting region 2110B to prevent an EMI phenomenon between the first and second chip mounting regions 2110A and 2110B. In some embodiments, the unit semiconductor package 13 may be singulated to include a single chip mounting region according to a singulation process.

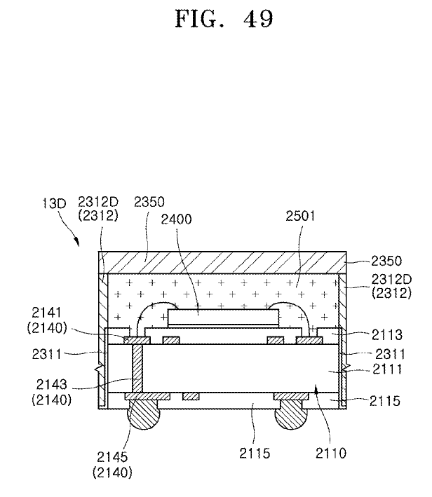

FIG. 49 is a cross-sectional view illustrating a semiconductor package 13D according to another embodiment. FIG. 49 is a cross-sectional view taken along a line X-X′ of FIG. 1.

As illustrated in FIG. 49, the unit semiconductor package 13D may be singulated to include one chip mounting region 2110. The unit semiconductor package 13D may be singulated to include a structure with side shielding parts 2312D surrounding sidewalls of a unit package substrate 2100N to horizontally shield the unit package substrate 2100N. A semiconductor chip 2400 may be mounted on the chip mounting region 2110. The side shielding parts 2312D may surround sidewalls of a mold pattern 2501 to horizontally shield the semiconductor chip 2400. A top shielding part 2350 may be disposed to cover top surfaces of the side shielding parts 2312D and the mold pattern 2501.

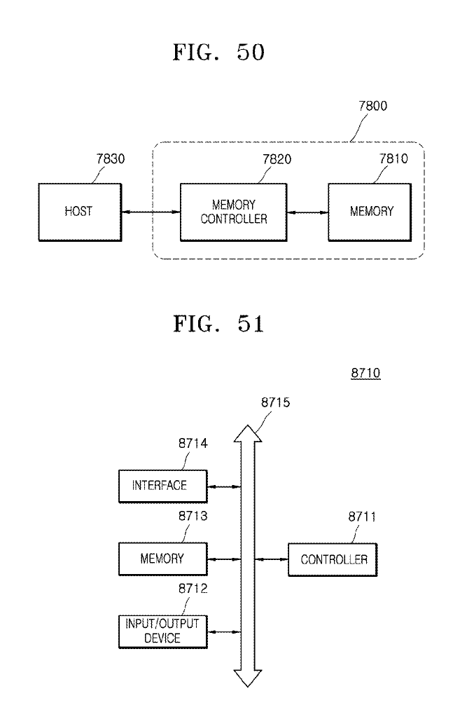

FIG. 50 is a block diagram illustrating an electronic system including a memory card 7800 including at least one semiconductor package according to an embodiment. The memory card 7800 includes a memory 7810 such as a nonvolatile memory device and a memory controller 7820. The memory 7810 and the memory controller 7820 may store data or read stored data. The memory 7810 and/or the memory controller 7820 may include one or more semiconductor chips disposed in a semiconductor package according to an embodiment.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

FIG. 51 is a block diagram illustrating an electronic system 8710 including at least one package according to an embodiment. The electronic system 8710 may include a controller 8711, an input/output device 8712, and a memory 8713. The controller 8711, the input/output device 8712 and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include one or more of the semiconductor packages according to embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is equipment capable of performing wireless communications, the electronic system 8710 may be used in a communication system such as CDMA (code division multiple access), GSM (global system for mobile communications), NADC (North American digital cellular), E-TDMA (enhanced-time division multiple access), WCDAM (wideband code division multiple access), CDMA2000, LTE (long term evolution) and Wibro (wireless broadband Internet).

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor package comprising:
a package substrate strip including a plurality of chip mounting regions, bridge regions connecting the plurality of chip mounting regions to each other, and a plurality of through slits disposed between the plurality of chip mounting regions;
a first side shielding part comprised of a conductive material filling the through slits;
a second side shielding part that vertically overlaps with the first side shielding part to upwardly protrude from the package substrate strip;
a plurality of semiconductor chips mounted on the plurality of chip mounting regions;
mold patterns disposed on the package substrate strip to cover the plurality of semiconductor chips and to expose a top surface of the second side shielding part; and
a top shielding part covering the mold patterns and contacting the top surface of the second side shielding part.

2. The semiconductor package of claim 1,
wherein the through slits are disposed to penetrate the package substrate strip between the plurality of chip mounting regions; and
wherein each of the bridge regions is disposed between two adjacent through slits.

3. The semiconductor package of claim 1,
wherein each of the plurality of chip mounting regions has a rectangular shape in a plan view; and
wherein the bridge regions are located at four corner edges of the plurality of chip mounting regions.

4. The semiconductor package of claim 1, wherein each of the bridge regions includes:
a bridge body layer comprised of a dielectric material; and
a first bridge trace pattern disposed on a first surface of the bridge body layer to contact the first side shielding part,
wherein the first bridge trace pattern is grounded.

5. The semiconductor package of claim 4, wherein the first bridge trace pattern overlaps with an extension of the first side shielding part and contacts the extension of the first side shielding part.

6. The semiconductor package claim 4, wherein each of the bridge regions further includes a second bridge trace pattern disposed on a second surface of the bridge body layer opposite to the first bridge trace pattern.

7. The semiconductor package of claim 4, wherein the package substrate strip further includes edge shielding pillars that penetrate package substrate bodies corresponding to portions of the package substrate strip between the bridge regions and the chip mounting regions to partially shield the chip mounting regions in a horizontal direction.

8. The semiconductor package of claim 7, wherein the edge shielding pillars in each of the package substrate bodies are electrically connected to the first bridge trace pattern.

9. The semiconductor package of claim 7,
wherein the edge shielding pillars in each of the package substrate bodies are arrayed in at least two columns; and
wherein the edge shielding pillars in two adjacent columns are arrayed in a zigzag fashion along a direction parallel with the columns.

10. The semiconductor package of claim 7, wherein the edge shielding pillars in each of the package substrate bodies are arrayed in one column to be in contact with each other.

11. The semiconductor package of claim 4, wherein the package substrate strip further includes edge shielding pillars that penetrate the bridge body layer to partially shield the chip mounting regions in a horizontal direction.

12. The semiconductor package of claim 1,
wherein the first side shielding part includes a first conductive adhesive; and
wherein the second side shielding part includes a second conductive adhesive which is different from the first conductive adhesive.

13. The semiconductor package of claim 1, wherein the second side shielding part has a shape of a grid that provides cavities exposing the chip mounting regions.

14. The semiconductor package of claim 1, wherein the second side shielding part extends to overlaps with portions of the bridge regions.

15. The semiconductor package of claim 1, wherein a top surface of the second side shielding part is located at a level which is higher than top surfaces of the semiconductor chips.

16. A semiconductor package comprising:
a package substrate including a chip mounting region, through slits defining the chip mounting region, and bridge regions disposed between the through slits along a periphery of the chip mounting region;
a first side shielding part comprised of a conductive material filling the through slits to horizontally shield the chip mounting region;
a second side shielding part that vertically overlaps with the first side shielding part to upwardly protrude from the package substrate;
a semiconductor chip mounted on the chip mounting region;
a mold pattern disposed on the package substrate to cover the semiconductor chip and to expose a top surface of the second side shielding part; and
a top shielding part covering the mold pattern and contacting the top surface of the second side shielding part.

17. The semiconductor package of claim 16, wherein the first side shielding part penetrates the package substrate along the periphery of the chip mounting region.

18. The semiconductor package of claim 16, wherein the package substrate further includes edge shielding pillars that penetrate bodies of the package substrate between the bridge regions and the chip mounting region to partially shield the chip mounting region in a horizontal direction.

19. The semiconductor package of claim 16, wherein the package substrate further includes edge shielding pillars that penetrate bridge body layers of the package substrate of the bridge regions to partially shield the chip mounting region in a horizontal direction.

20. A semiconductor package comprising:
a package substrate strip including a plurality of chip mounting regions, bridge regions connecting the plurality of chip mounting regions to each other, and a plurality of through slits disposed between the plurality of chip mounting regions;
a side shielding part including a lower side shielding part filling the through slits and an upper side shielding part upwardly extending from the lower side shielding part to protrude from the package substrate strip;
a plurality of semiconductor chips mounted on the plurality of chip mounting regions;
mold patterns disposed on the package substrate strip to cover the plurality of semiconductor chips and to expose a top surface of the side shielding part; and
a top shielding part disposed on the mold patterns to contact the top surface of the side shielding part.
